(19) United States
(12) Patent Application Publication
(10) Pub. No.: US 2026/0305076 A1
(43) Pub. Date: Oct. 1, 2026

(54) DISPLAY DEVICE, ELECTRONIC DEVICE AND METHOD OF MANUFACTURING DISPLAY DEVICE

(71) Applicant: Samsung Display Co., Ltd., Yongin-Si (KR)

(72) Inventors: Dan Bi YANG, Yongin-si (KR); Min Hee KIM, Yongin-si (KR); Jae Cheol PARK, Yongin-si (KR); Sim Bum YUK, Yongin-si (KR)

(21) Appl. No.: 19/385,155

(22) Filed: Nov. 11, 2025

(30) Foreign Application Priority Data
Mar. 31, 2025 (KR) 10-2025-0040921

(51) Int. Cl. H10K 59/122; H10K 59/12; H10K 59/80

(52) U.S. Cl. CPC H10K 59/122; H10K 59/1201; H10K 59/8792

(57) ABSTRACT

A display device according to an embodiment includes a substrate, a light emitting element layer disposed on the substrate and including a pixel defining layer defining emission areas and light emitting elements disposed in the emission areas, and a light conversion layer disposed on the light emitting element layer and including a bank defining light transmitting areas each of which is disposed on one of the emission areas and light conversion members disposed in the light transmitting areas, wherein the bank includes, a partition wall portion having a width smaller than a width of the pixel defining layer and overlapping a central portion of the pixel defining layer, and an extending portion extending from a lower end portion of the partition wall portion toward the light transmitting areas.

### CROSS-REFERENCE TO RELATED APPLICATION

This application claims priority from Korean Patent Application No. 10-2025-0040921 filed on Mar. 31, 2025, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and an electronic device capable of displaying an image, and a method of manufacturing the display device.

### 2. Description of the Related Art

As the information society develops, the demand for display devices and electronic devices capable of displaying images has increased and diversified. Accordingly, various types of display devices and electronic devices including pixels for displaying images have been developed. The display device may be provided alone or may be included in an electronic device and used as a display screen of the electronic device.

### SUMMARY

Aspects of the present disclosure provide a display device and an electronic device capable of improving color expressiveness, and a method of manufacturing the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including, a substrate, a light emitting element layer disposed on the substrate and including a pixel defining layer defining emission areas and light emitting elements disposed in the emission areas, and a light conversion layer disposed on the light emitting element layer and including a bank defining light transmitting areas each of which is disposed on one of the emission areas and light conversion members disposed in the light transmitting areas, wherein the bank includes, a partition wall portion having a width smaller than a width of the pixel defining layer and overlapping a central portion of the pixel defining layer, and an extending portion extending from a lower end portion of the partition wall portion toward the light transmitting areas.

In an embodiment, a bottom surface of the bank including the extending portion may have a width less than or equal to the width of the pixel defining layer and the bottom surface of the bank including the extending portion may completely overlap the pixel defining layer.

In an embodiment, the bank may include a hydrophobic polymer.

In an embodiment, the pixel defining layer may include a first colorant, and the bank may include a second colorant having a lower optical density than the first colorant.

In an embodiment, the first colorant may be a black colorant, and the second colorant may be a purple colorant.

In an embodiment, a thickness of the extending portion of the bank may be 2 μm or more.

In an embodiment, the emission areas may include a first emission area, a second emission area, and a third emission area, and the light emitting elements may include a first light emitting element, a second light emitting element, and a third light emitting element respectively disposed in the first emission area, the second emission area, and the third emission area and each of the first light emitting element, the second light emitting element and the third light emitting element emitting light of the same color.

In an embodiment, the light conversion members may include, a first light conversion member disposed on the first light emitting element and converting the light emitted from the first light emitting element into light of a first color, a second light conversion member disposed on the second light emitting element and converting the light emitted from the second light emitting element into light of a second color, and a third light conversion member disposed on the third light emitting element and transmitting the light emitted from the third light emitting element.

In an embodiment, the display device may further include a color filter unit disposed on the light conversion layer, and the color filter unit may include a first color filter disposed on the first light conversion member, a second color filter disposed on the second light conversion member, and a third color filter disposed on the third light conversion member.

In an embodiment, each of the light emitting elements may include a first electrode, a light emitting layer, and a second electrode that are sequentially disposed on the substrate, the first electrode in each of the light emitting elements may be disposed in each of the emission areas as separate units, and the light emitting layer and the second electrode may be disposed over an entire display area including the emission areas.

In an embodiment, the pixel defining layer may include a first opening corresponding to a first emission area of the emission areas, the partition wall portion of the bank may include a second opening corresponding to a first light transmitting area overlapping the first emission area among the light transmitting areas, and an area of the second opening may be greater than an area of the first opening.

In an embodiment, in plan view, the first opening may be disposed inside the second opening.

In an embodiment, the light transmitting areas may be defined by the partition wall portion of the bank, and in plan view, sizes of the light transmitting areas may be greater than sizes of the emission areas, and edges of the light transmitting areas may be located outside the emission areas.

According to an aspect of the present disclosure, there is provided an electronic device including, a display module including a display panel, and a processor transmitting an image data signal to the display module, wherein the display panel includes, a substrate, a light emitting element layer disposed on the substrate and including a pixel defining layer defining emission areas and light emitting elements disposed in the emission areas, and a light conversion layer disposed on the light emitting element layer and including a bank defining light transmitting areas each of which is disposed on one of the emission areas and light conversion members disposed in the light transmitting areas, and the bank includes, a partition wall portion having a width smaller than a width of the pixel defining layer and overlapping a central portion of the pixel defining layer, and an extending portion extending from a lower end portion of the partition wall portion toward the light transmitting areas.

In an embodiment, a bottom surface of the bank including the extending portion may have a width less than or equal to the width of the pixel defining layer and the bottom surface of the bank including extending portion may completely overlap the pixel defining layer.

In an embodiment, the bank may include a hydrophobic polymer.

In an embodiment, the pixel defining layer may include a first colorant, and the bank may include a second colorant having a lower optical density than the first colorant.

In an embodiment, the emission areas may include a first emission area, a second emission area, and a third emission area, the light emitting elements may include a first light emitting element, a second light emitting element, and a third light emitting element respectively disposed in the first emission area, the second emission area, and the third emission area and each of the first light emitting element, the second light emitting element and the third light emitting element emitting light of the same color, and the light conversion members may include a first light conversion member disposed on the first light emitting element and converting the light emitted from the first light emitting element into light of a first color, a second light conversion member disposed on the second light emitting element and converting the light emitted from the second light emitting element into light of a second color, and a third light conversion member disposed on the third light emitting element and transmitting the light emitted from the third light emitting element.

According to an aspect of the present disclosure, there is provided a method of manufacturing a display device, including, forming a light emitting element layer on the substrate, the light emitting element layer including a pixel defining layer defining emission areas and light emitting elements disposed in the emission areas, and forming a light conversion layer on the light emitting element layer, the light conversion layer including a bank defining light transmitting areas each of which is disposed on one of the emission areas and light conversion members disposed in the light transmitting areas, wherein the forming of the bank includes, forming a bank material layer on the light emitting element layer, the bank material layer including a deep portion curing initiator and a hydrophobic polymer, disposing a half-tone mask on the bank material layer and exposing the bank material layer using the half-tone mask, and forming the bank by developing the bank material layer.

In an embodiment, in the exposing of the bank material layer using the half-tone mask, a full-tone portion of the half-tone mask may be disposed on a portion of the bank material layer overlapping a central portion of the pixel defining layer, half-tone portions of the half-tone mask may be disposed on other portions of the bank material layer overlapping edge portions of the pixel defining layer, and non-tone portions of the half-tone mask may be disposed on the remaining portions of the bank material layer overlapping openings of the pixel defining layer.

With a display device, an electronic device, and a method of manufacturing the display device according to embodiments, by forming an extending portion integrally extending from a partition wall portion of a bank at a lower end portion of the bank defining light transmitting areas where light incident from light emitting elements is converted and/or transmitted, it is possible to effectively block or reduce lateral light leakage between pixels. Accordingly, color expressiveness of the display device and the electronic device may be improved.

In some embodiments, the bank including the extending portion may have a width less than or equal to a width of a pixel defining layer, and may not invade emission areas defined by the pixel defining layer. Accordingly, an aperture ratio of the display device and the electronic device may be secured or improved.

In some embodiments, the partition wall portion and the extending portion of the bank may be simultaneously formed using a half-tone mask. Accordingly, manufacturing efficiency of the display device and the electronic device may be increased.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings.

FIG. 1 is a perspective view illustrating a display device according to an embodiment.

FIG. 2 is a plan view illustrating main components of the display device of FIG. 1.

FIG. 3 is a schematic cross-sectional view illustrating a display panel of FIG. 2.

FIG. 4 is an equivalent circuit diagram illustrating a pixel according to an embodiment.

FIG. 5 is a plan view illustrating emission areas disposed in a display area of the display device according to an embodiment.

FIG. 6 is a plan view illustrating light transmitting areas arranged in the display area of the display device according to an embodiment.

FIG. 7 is a cross-sectional view illustrating the display panel of the display device according to an embodiment.

FIG. 8 is an enlarged view of area A2 of FIG. 7.

FIG. 9 is an enlarged view of area A3 of FIG. 7.

FIG. 10 is a graph illustrating color expressiveness of the display device according to characteristics of a bank.

FIG. 11 is a cross-sectional view illustrating a portion of a method of manufacturing the display device according to an embodiment.

FIG. 12 is cross-sectional view illustrating a portion of the method of manufacturing the display device according to an embodiment.

FIG. 13 is cross-sectional view illustrating a portion of the method of manufacturing the display device according to an embodiment.

FIG. 14 is cross-sectional view illustrating a portion of the method of manufacturing the display device according to an embodiment.

FIG. 15 is cross-sectional view illustrating a portion of the method of manufacturing the display device according to an embodiment.

FIG. 16 is cross-sectional view illustrating the portion of a method of manufacturing the display device according to an embodiment.

FIG. 17 is a block diagram of an electronic device according to an embodiment.

FIG. 18 is schematic views of electronic devices according to various embodiments.

### DETAILED DESCRIPTION OF THE EMBODIMENTS

The present disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

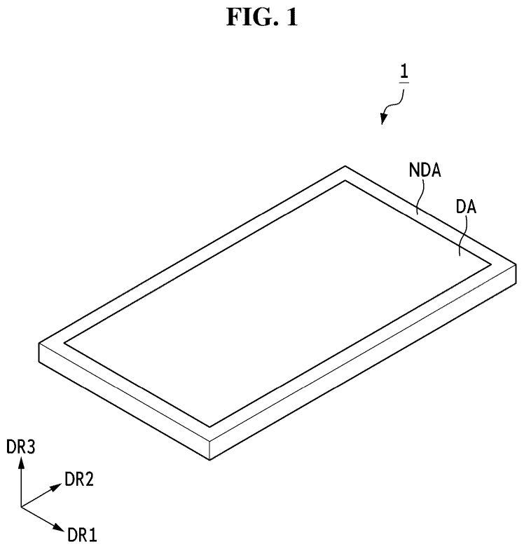

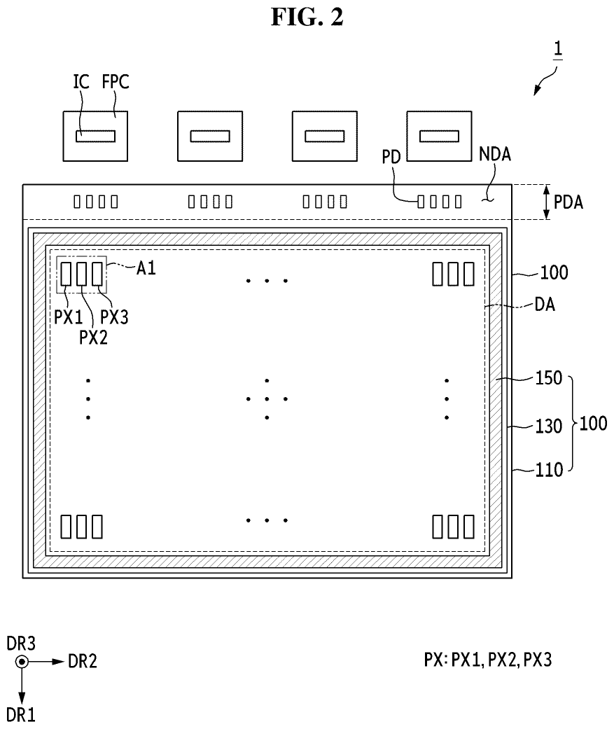

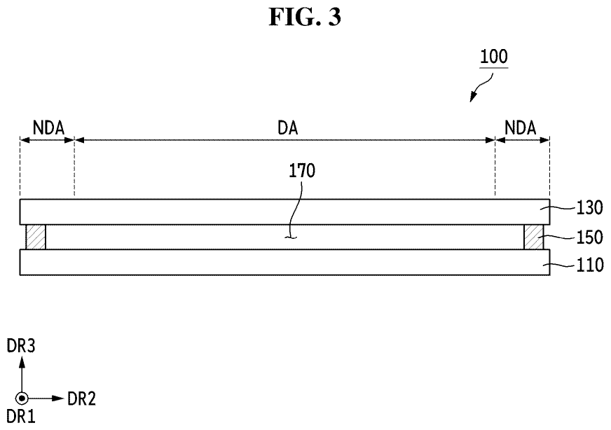

FIG. 1 is a perspective view illustrating a display device according to an embodiment. FIG. 2 is a plan view illustrating main components of the display device of FIG. 1. FIG. 3 is a schematic cross-sectional view illustrating a display panel of FIG. 2.

Referring to FIGS. 1 to 3, a display device 1 is a device that displays a moving image or a still image, and may be included in various electronic devices capable of displaying images, such as televisions, laptop computers, monitors, billboards, the Internet of Things (IOT), virtual reality (VR) devices, and augmented reality (AR) devices, as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). In an embodiment, an electronic device including the display device 1 may further include a display device housing portion in which the display device 1 is housed and/or a case or a cover for protecting the display device 1.

The display device 1 may be a light emitting display device such as an organic light emitting display device including organic light emitting diodes, a quantum dot light emitting display device including quantum dot light emitting layers, an inorganic light emitting display device including inorganic semiconductors, or a micro light emitting display device including micro light emitting diodes such as micro or nano light emitting diodes (micro LEDs or nano LEDs), but is not limited thereto. For example, the display device 1 may also be a type of display device other than the light emitting display device. Hereinafter, embodiments in which the display device 1 is an organic light emitting display device have been disclosed.

In FIGS. 1 to 3, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. As an example, the first direction DR1 may refer to a longitudinal direction of the display device 1, the second direction DR2 may refer to a transverse direction of the display device 1, and the third direction DR3 may refer to a thickness direction (or a height direction) of the display device 1. In the following description, unless otherwise specified, the term “direction” may refer to both directions toward opposite sides extending along the direction. In addition, when both “directions” extending to opposite sides need to be distinguished from each other, one side may be referred to as “one side in the direction” and the other side may be referred to as “the other side in the direction”.

In referring to surfaces of the display device 1 or respective members constituting the display device 1, one surface facing one side in a direction (e.g., the third direction DR3) in which the image is displayed may be referred to as an upper surface, a front surface, a first surface, or the like, and a surface opposite to the one surface may be referred to as a lower surface, a rear surface, a second surface, or the like. In addition, in describing relative locations of the respective members of the display device 1, one side in the third direction DR3 may be referred to as an upper portion and the other side in the third direction DR3 may be referred to as a lower portion.

The display device 1 may have a three-dimensional shape. For example, the display device 1 may have a rectangular parallelepiped shape or a three-dimensional shape similar to the rectangular parallelepiped shape. In an embodiment, the display device 1 may have a quadrangular shape or a shape similar to the quadrangular shape in plan view. For example, the display device 1 may have a rectangular shape having short sides in the first direction DR1 and long sides in the second direction DR2 or a shape similar to the rectangular shape, in plan view. A corner where the short side in the first direction DR1 and the long side in the second direction DR2 of the display device 1 meet may be rounded or angled (e.g., right-angled). The display device 1 may have various shapes in addition to the shapes described above.

The display device 1 may include a display area DA where an image is displayed and a non-display area NDA where an image is not displayed. The non-display area NDA may be disposed around the display area DA. In some embodiments, the display area DA may be disposed at a central portion of the display device 1, and the non-display area NDA may be disposed at an edge portion of the display device 1 to surround the display area DA. The display device 1 may emit light to one side in the third direction DR3, and accordingly, a user may view the image displayed in the display area DA on one side in the third direction DR3.

The display device 1 may include a display panel 100 for configuring a screen, as illustrated in FIGS. 2 and 3. The display device 1 may further include at least one flexible circuit board FPC and a driving circuit chip IC electrically connected to the display panel 100. The display panel 100, the flexible circuit board FPC, and the driving circuit chip IC may constitute a display module, which is a core element of the display device 1.

The display panel 100 may include a display area DA and a non-display area NDA.

Pixels PX may be disposed in the display area DA. For example, the display panel 100 may include a first pixel PX1, a second pixel PX2, and a third pixel PX3 that are disposed in the display area DA and respectively emit light of a first color (e.g., red light having a main peak wavelength of approximately 600 nm to 750 nm), light of a second color (e.g., green light having a main peak wavelength of approximately 480 nm to 560 nm), and light of a third color (e.g., blue light having a main peak wavelength of approximately 370 nm to 480 nm). A plurality of first pixels PX1, second pixels PX2, and third pixels PX3 may be repeatedly arranged in the display area DA.

At least one first pixel PX1, at least one second pixel PX2, and at least one third pixel PX3 adjacent to each other may constitute one unit pixel. As an example, one first pixel PX1, one second pixel PX2, and one third pixel PX3 disposed in area A1 of FIG. 2 may constitute one unit pixel. The unit pixel may be a minimum unit capable of expressing various colors including white.

An embodiment in which the first pixel PX1, the second pixel PX2, and the third pixel PX3 constituting one unit pixel are sequentially arranged along the second direction DR2 has been illustrated in FIG. 2. However, an arrangement form or a location of the first pixel PX1, the second pixel PX2, and the third pixel PX3 are not limited thereto, and may be variously changed according to embodiments. In addition, types, sizes, shapes, the number, a ratio, and the like, of pixels PX constituting each unit pixel may also be variously changed according to embodiments.

The display panel 100 may include a light emitting unit (or light emitting portion) 110 and a color filter unit (or color filter portion) 130 facing the light emitting unit 110.

The light emitting unit 110 may include light emitting elements of the pixels PX. In an embodiment, the light emitting unit 110 may further include circuit elements of the pixels PX. For example, the light emitting unit 110 may be a display substrate including a backplane layer including circuit elements (e.g., thin film transistors) of the pixels PX and light emitting elements (e.g., organic light emitting diodes) of the pixels PX disposed on the backplane layer. In an embodiment, the light emitting unit 110 may further include a light conversion layer including light conversion members disposed on the light emitting elements of the pixels PX. The light conversion members may be considered as components included in the respective pixels PX, but are not limited thereto. For example, the light conversion members may also be considered as separate components distinguished from the pixels PX.

The color filter unit 130 may include color filters disposed on the light emitting elements of the pixels PX and the light conversion members. The color filters may selectively transmit light corresponding to an emission wavelength of each of the pixels PX.

The non-display area NDA of the display panel 100 may include a pad area PDA where pads PD are disposed. In an embodiment, the pads PD may be formed at one end of the backplane layer included in the light emitting unit 110 of the display panel 100.

In some embodiments, the display panel 100 may further include a gate driver (not illustrated) disposed in the non-display area NDA. As an example, the display panel 100 may include an embedded gate driver including the circuit elements formed in the backplane layer of the light emitting unit 110 together with the circuit elements included in the pixels PX. In an embodiment, the gate driver may be disposed in a portion of the non-display area NDA adjacent to the display area DA (e.g., a portion of the non-display area NDA located on the left side and/or the right side of the display area DA), and may be disposed in a sealing area surrounded by a sealant 150. The gate driver may be electrically connected to a circuit board or the like disposed outside the display panel 100 via the pads PD to receive a timing control signal or the like, and may output gate signals including scan signals in response to the timing control signal. The gate signals may be transmitted to the pixels PX through gate lines electrically connected between the gate driver and the pixels PX.

In an embodiment, the display panel 100 may further include a sealant 150 and a filler 170 that are disposed between the light emitting unit 110 and the color filter unit 130.

The sealant 150 may be disposed in the non-display area NDA so as to surround the display area DA, and may couple the light emitting unit 110 and the color filter unit 130 to each other. For example, the light emitting unit 110 and the color filter unit 130 may be coupled to each other via the sealant 150.

The filler 170 may be filled between the light emitting unit 110 and the color filter unit 130. For example, the filler 170 may fill a space between the light emitting unit 110 and the color filter unit 130 surrounded by the sealant 150. The filler 170 may include a light transmitting material (e.g., a light transmitting organic material), and may be substantially transparent so that light emitted from the light emitting unit 110 may be transmitted. Depending on a sealing structure or a sealing method of the display panel 100, the display panel 100 may not include the sealant 150 and the filler 170.

The flexible circuit board FPC may be disposed on the pads PD, and may be electrically connected to the pads PD. The flexible circuit board FPC may electrically connect a circuit board or the like providing signals, source voltages, and the like, for driving the display device 1 and the light emitting unit 110 to each other.

The driving circuit chip IC may be electrically connected to the circuit board or the like to receive an image data signal, a timing control signal, and the like. In some embodiments, the driving circuit chip IC may be a data driving circuit chip IC including a data driver, and may output data signals (e.g., respective data voltages corresponding to image data) for controlling luminance of the pixels PX.

In some embodiments, the driving circuit chip IC may be mounted on the flexible circuit board FPC. For example, the driving circuit chip IC may be mounted on the flexible circuit board FPC in the form of a chip on film (COF), but is not limited thereto.

The data signals provided from the driving circuit chip IC and driving voltages provided from the circuit board may be transmitted to the pixels PX of the light emitting unit 110 via the flexible printed circuit board FPC and the pads PD.

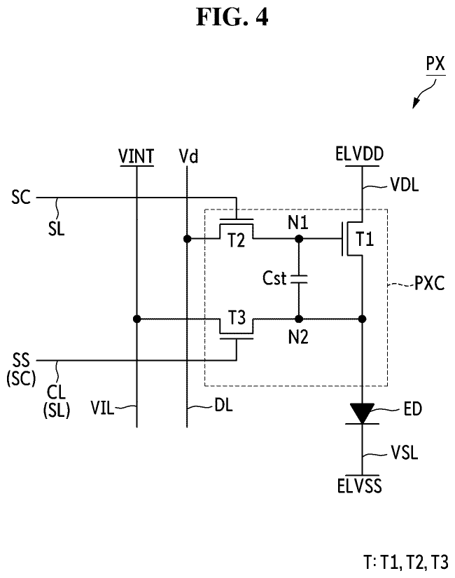

FIG. 4 is an equivalent circuit diagram illustrating a pixel according to an embodiment. For example, FIG. 4 illustrates a pixel PX of a light emitting display device including a light emitting element ED. Any pixel PX that may be included in the display device 1 according to an embodiment is illustrated in FIG. 4. As an example, the pixel PX of FIG. 4 may be one of the first pixel PX1, the second pixel PX2, and the third pixel PX3 of FIG. 2. In an embodiment, circuit configurations of the first pixel PX1, the second pixel PX2, and the third pixel PX3 may be substantially the same as each other.

Referring to FIG. 4, the pixel PX may include a light emitting element ED and a pixel circuit PXC connected to the light emitting element ED. The light emitting element ED may be an organic light emitting diode, but is not limited thereto. The pixel circuit PXC may control light emission of the light emitting element ED.

The pixel circuit PXC may include transistors T and a capacitor Cst. For example, the pixel circuit PXC may include a first transistor T1, a second transistor T2, and a third transistor T3, and a capacitor Cst. An embodiment in which the transistors T are all N-type transistors has been illustrated in FIG. 3, but embodiments are not limited thereto. For example, at least one transistor T may also be formed as a P-type transistor. In addition, a structure or an operation method of the pixel circuit PXC may be variously changed according to embodiments.

The pixel circuit PXC may supply a driving current to the light emitting element ED in response to driving signals supplied from the gate driver (e.g., the embedded gate driver disposed in the non-display area NDA of the display panel 100) and the data driver (e.g., the driving circuit chip IC of FIG. 2). For example, the pixel circuit PXC may supply the driving current to the light emitting element ED in response to a scan signal SC and a control signal SS supplied from the gate driver via a scan line SL and a control line CL, respectively, and a data signal Vd supplied from the data driver via a data line DL or the like.

An embodiment in which the scan line SL and the control line CL are separated from each other has been illustrated in FIG. 4, but embodiments are not limited thereto. For example, the control line CL is a portion of the scan line SL and may branch from the scan line SL, and the control signal SS may be the scan signal SC.

The first transistor T1 may be a driving transistor of the pixel PX whose magnitude of a drain-source current (e.g., the driving current) is determined according to its gate-source voltage. The second and third transistors T2 and T3 may be switching transistors that are turned on or off depending on their respective gate-source voltages. Depending on a type (e.g., a P-type or N-type transistor) and/or an operation condition of each of the transistors T, a first electrode of each of the transistors T may be a drain electrode (or a drain region) or a source electrode (or a source region), and a second electrode of each of the transistors T may be an electrode different from the first electrode. For example, when the first electrode is the drain electrode, the second electrode may be the source electrode.

The pixel PX may be connected to the scan line SL transmitting the scan signal SC, the control line CL transmitting the control signal SS (e.g., a sensing control signal or an initialization control signal), and the data line DL transmitting the data signal Vd. In addition, the pixel PX may be connected to a first power line VDL transmitting a first driving voltage ELVDD (also referred to as a “first pixel voltage”) and a second power line VSL transmitting a second driving voltage ELVSS (also referred to as a “second pixel voltage”). A voltage level of the second driving voltage ELVSS may be lower than a voltage level of the first driving voltage ELVDD. In an embodiment, the pixel PX may be further connected to an initialization power line VIL transmitting an initialization voltage VINT (also referred to as a “third pixel voltage”).

In an embodiment, the transistors T may be located in respective pixel areas, and may be oxide transistors each including an oxide semiconductor. For example, an active layer of each of the first, second, and third transistors T1, T2, and T3 may include an oxide semiconductor. However, embodiments are not limited thereto. For example, at least one transistor T may also be made of a semiconductor material (e.g., amorphous silicon or polysilicon) other than the oxide semiconductor.

In an embodiment, a light blocking layer, a bottom electrode, or the like, may be disposed below the active layer of at least one of the first, second, and third transistors T1, T2, and T3. As an example, a bottom metal layer blocking external light may be disposed below the active layer of the first transistor T1. Accordingly, operation characteristics of the first transistor T1 may be stabilized.

The first transistor T1 may include a gate electrode connected to a first node N1, a first electrode (e.g., a drain electrode) connected to the first power line VDL, and a second electrode (e.g., a source electrode) connected to a second node N2. The first transistor T1 may control the driving current of the pixel PX in response to the data signal Vd transmitted to the first node N1.

The second transistor T2 may include a gate electrode connected to the scan line SL, a first electrode connected to the data line DL, and a second electrode connected to the first node N1. The second transistor T2 may be turned on by the scan signal SC of a gate-on voltage applied to the scan line SL to connect the data line DL and the first node N1 to each other. Accordingly, the data signal Vd applied to the data line DL may be transmitted to the first node N1.

The third transistor T3 may include a gate electrode connected to the control line CL (or the scan line SL), a first electrode connected to the second node N2, and a second electrode connected to the initialization voltage line VIL. The third transistor T3 may be turned on by the control signal SS (or the scan signal SC) of a gate-on voltage applied to the control line CL (or the scan line SL) to connect the initialization voltage line VIL and the second node N2 to each other.

The capacitor Cst may be connected between the first node N1 and the second node N2. The capacitor Cst may store a voltage corresponding to the data signal Vd (e.g., a data voltage) transmitted to the first node N1.

The light emitting element ED may be connected between the pixel circuit PXC and the second power line VSL. For example, the light emitting element ED may include a first electrode (e.g., an anode electrode) connected to the pixel circuit PXC through the second node N2, a second electrode (e.g., a cathode electrode) facing the first electrode and connected to the second power line VSL, and a light emitting layer interposed between the first electrode and the second electrode. In an embodiment, the first electrode of the light emitting element ED may be a pixel electrode individually provided to each pixel PX, and the second electrode of the light emitting element ED may be a common electrode shared by a plurality of pixels PX. The light emitting element ED may emit light with luminance corresponding to the driving current during a period in which the driving current is supplied from the pixel circuit PXC.

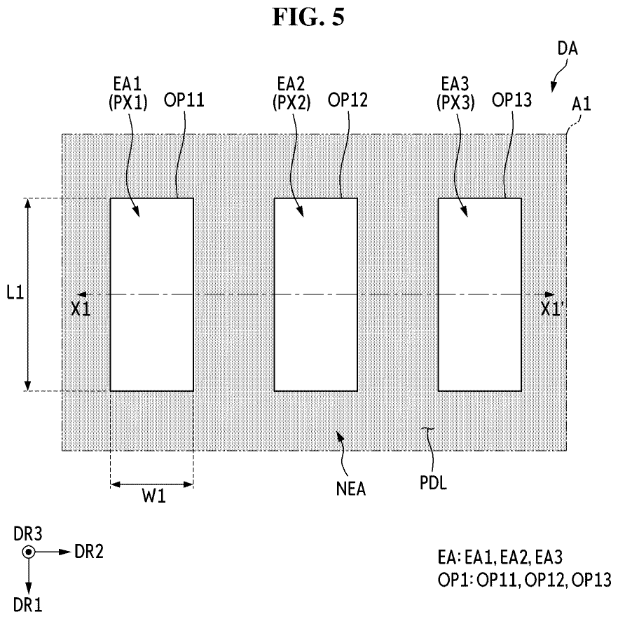

FIG. 5 is a plan view illustrating emission areas disposed in a display area of the display device according to an embodiment. For example, FIG. 5 illustrates emission areas EA of pixels PX disposed in area A1 of FIG. 2.

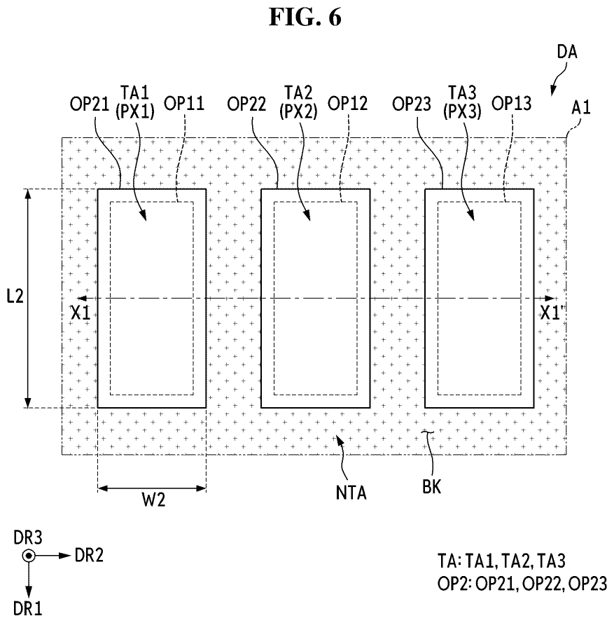

FIG. 6 is a plan view illustrating light transmitting areas arranged in the display area of the display device according to an embodiment. For example, FIG. 6 illustrates light transmitting areas TA of the pixels PX disposed in area A1 of FIG. 2.

An embodiment in which the emission areas EA of the pixels PX are sequentially arranged in the second direction DR2 and have the same size has been illustrated in FIGS. 5 and 6, but embodiments are not limited thereto. For example, an arrangement structure of the emission areas EA disposed in the display area DA, a size and/or a shape of each of the emission areas EA, and the like, may be variously changed according to embodiments. In addition, an arrangement structure of the light transmitting areas TA disposed in the display area DA, a size and/or a shape of each of the light transmitting areas TA, and the like, may be variously changed according to embodiments.

Referring to FIGS. 5 and 6 in addition to FIGS. 1 to 4, the display area DA may include the emission areas EA and the light transmitting areas TA of the pixels PX. The emission area EA and the light transmitting area TA of each of the pixels PX may correspond to each other. For example, the emission area EA and the light transmitting area TA of each of the pixels PX may overlap each other in the third direction DR3, and may have shapes and/or sizes similar to each other.

The emission areas EA are areas where the light emitting elements ED of the pixels PX are disposed, and may be areas where light is generated and emitted by the light emitting elements ED. For example, the emission areas EA may include a first emission area EA1 where the light emitting element ED of the first pixel PX1 is disposed, a second emission area EA2 where the light emitting element ED of the second pixel PX2 is disposed, and a third emission area EA3 where the light emitting element ED of the third pixel PX3 is disposed.

The emission areas EA may be defined and/or partitioned by a pixel defining layer PDL. For example, the pixel defining layer PDL may be disposed in a non-emission area NEA to surround the emission areas EA.

The pixel defining layer PDL may include first openings OP1 corresponding to the emission areas EA. For example, the pixel defining layer PDL may include a first opening OP11 corresponding to the first emission area EA1, a first opening OP12 corresponding to the second emission area EA2, and a first opening OP13 corresponding to the third emission area EA3. The first openings OP1 of the pixel defining layer PDL may expose the light emitting elements ED disposed in the respective emission areas EA.

The light transmitting areas TA may be areas where the light generated from the light emitting elements ED of the pixels PX is converted and/or transmitted. For example, the light generated from the light emitting elements ED disposed in the respective emission areas EA may be emitted to the outside via the respective light transmitting areas TA.

The light transmitting areas TA may include a first light transmitting area TA1 that is an area through which the light generated from the light emitting element ED of the first pixel PX1 is transmitted and corresponds to the first emission area EA1, a second light transmitting area TA2 that is an area through which the light generated from the light emitting element ED of the second pixel PX2 is transmitted and corresponds to the second emission area EA2, and a third light transmitting area TA3 that is an area through which the light generated from the light emitting element ED of the third pixel PX3 is transmitted and corresponds to the third emission area EA3. In plan view (e.g., when viewed on a plane defined by the first direction DR1 and the second direction DR2), the first light transmitting area TA1 may overlap the first emission area EA1, the second light transmitting area TA2 may overlap the second emission area EA2, and the third light transmitting area TA3 may overlap the third emission area EA3. For example, in the third direction DR3, the first light transmitting area TA1, the second light transmitting area TA2, and the third light transmitting area TA3 may be disposed on the first emission area EA1, the second emission area EA2, and the third emission area EA3, respectively.

In an embodiment, light conversion members converting a color and/or a wavelength of the light generated from the respective light emitting elements ED may be disposed in at least some light transmitting areas TA. In this case, the pixels PX including the light conversion members may emit light of colors and/or wavelengths different from the color and/or the wavelength of the light generated from the respective light emitting elements ED.

The light transmitting areas TA may be defined and/or partitioned by a bank BK disposed on the pixel defining layer PDL. For example, the bank BK may be disposed in a light blocking area NTA to surround the light transmitting areas TA.

The bank BK may include second openings OP2 corresponding to the light transmitting areas TA. For example, the bank BK may include a second opening OP21 corresponding to the first light transmitting area TA1, a second opening OP22 corresponding to the second light transmitting area TA2, and a second opening OP23 corresponding to the third light transmitting area TA3. The second openings OP2 of the bank BK may expose the light conversion members disposed in the respective light transmitting areas TA.

In some embodiments, by reducing a width of the bank BK and extending areas of the light transmitting areas TA, it is possible to increase an aperture ratio of the light conversion layer including the light conversion members and/or the display device 1 including the light conversion layer. For example, the light transmitting area TA of each pixel PX may correspond to a portion where the light is converted and/or emitted in each pixel PX, and may extend to the vicinity of the emission area EA so as to have a greater area than the emission area EA of the corresponding pixel PX. As an example, in the first direction DR1, a length L2 of the first light transmitting area TA1 may be greater than a length L1 of the first emission area EA1. In addition, in the second direction DR2, a width W2 of the first light transmitting area TA1 may be greater than a width W1 of the first emission area EA1. In plan view, each light transmitting area TA may include each emission area EA, and an edge of the light transmitting area TA may be spaced apart from an edge of the emission area EA and located outside the emission area EA.

In this case, the second opening OP21 of the bank BK corresponding to the first light transmitting area TA1 may expose the first emission area EA1 and a portion of the pixel defining layer PDL located at a perimeter of the first emission area EA1. In addition, the second opening OP22 of the bank BK corresponding to the second light transmitting area TA2 may expose the second emission area EA2 and a portion of the pixel defining layer PDL located at a perimeter of the second emission area EA2, and the second opening OP23 of the bank BK corresponding to the third light transmitting area TA3 may expose the third emission area EA3 and a portion of the pixel defining layer PDL located at a perimeter of the third emission area EA3.

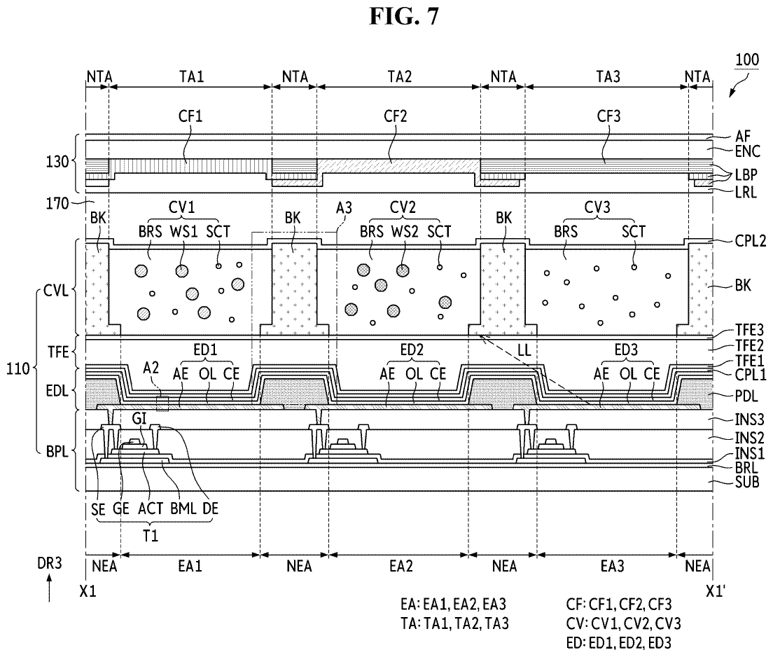

FIG. 7 is a cross-sectional view illustrating the display panel of the display device according to an embodiment. For example, FIG. 7 illustrates an example of a cross section of a portion of the display panel corresponding to lines X1 to X1′ of FIGS. 5 and 6.

Referring to FIG. 7 in addition to FIGS. 1 to 6, the display panel 100 according to an embodiment may include the light emitting unit 110 and the color filter unit 130. In an embodiment, the filler 170 may be filled between the light emitting unit 110 and the color filter unit 130.

The light emitting unit 110 according to an embodiment may include a backplane layer BPL, a light emitting element layer EDL, an encapsulation layer TFE, and a light conversion layer CVL. The light emitting element layer EDL, the encapsulation layer TFE, and the light conversion layer CVL may be sequentially disposed on the backplane layer BPL along the third direction DR3.

The backplane layer BPL may include a substrate SUB (e.g., a lower substrate) and insulating layers and circuit elements disposed on the substrate SUB.

The substrate SUB is a base member for forming the light emitting unit 110, and may be a rigid or flexible substrate (or film). In an embodiment, the substrate SUB may be a substrate including an insulating material such as glass and having rigid characteristics, and may not be bent. In an embodiment, the substrate SUB may be a flexible substrate including polyimide or other insulating materials and capable of being deformed, for example, bent, folded, or rolled, and may or may not be bent. A type and/or a material of the substrate SUB may be changed according to embodiments.

In an embodiment, the insulating layers of the backplane layer BPL may include a barrier layer BRL, a first insulating layer INS1, a gate insulating layer GI, a second insulating layer INS2, and a third insulating layer INS3. The barrier layer BRL, the first insulating layer INS1, the gate insulating layer GI, the second insulating layer INS2, and the third insulating layer INS3 may be sequentially disposed on the substrate SUB in the third direction DR3.

The barrier layer BRL, the first insulating layer INS1, and the second insulating layer INS2 may be disposed around conductive patterns (e.g., electrodes, lines, and/or connection patterns of the circuit elements) formed in the backplane layer BPL. The gate insulating layer GI may be disposed between active layers ACT and gate electrodes GE of transistors T disposed in the backplane layer BPL. For example, the gate insulating layer GI may be disposed between an active layer ACT and a gate electrode GE of each of the first transistors T1 included in the pixels PX. The third insulating layer INS3 may cover the conductive patterns formed in the backplane layer BPL.

At least one of the insulating layers of the backplane layer BPL may be disposed entirely in the display area DA. As an example, the barrier layer BRL, the first insulating layer INS1, the second insulating layer INS2, and the third insulating layer INS3 may be entirely disposed in the display area DA, and may overlap each other in the third direction DR3.

In an embodiment, the gate insulating layer GI may have a shape in which it is etched to cover only a portion of the active layer ACT (e.g., a portion of the active layer ACT including a channel region overlapping the gate electrode GE) included in each of the transistors T of the backplane layer BPL and expose another portion of the active layer ACT. However, embodiments are not limited thereto, and the gate insulating layer GI may also be entirely disposed in the display area DA to more entirely cover the active layers ACT of the transistors T.

Each of the insulating layers of the backplane layer BPL may include at least one inorganic insulating material and/or at least one organic insulating material, and may have a single-layer or multilayer structure. For example, each of the barrier layer BRL, the first insulating layer INS1, the gate insulating layer GI, and the second insulating layer INS2 may include at least one inorganic insulating layer including an inorganic insulating material (e.g., silicon nitride, silicon oxide, silicon oxynitride, titanium oxide, aluminum oxide, or other inorganic insulating materials). The third insulating layer INS3 may include at least one organic insulating layer including an organic insulating material (e.g., an acrylic resin, an epoxy resin, a phenolic resin, a polyamide resin, a polyimide resin, or other organic insulating materials). The third insulating layer INS3 may alleviate or planarize a step due to the conductive patterns of the backplane layer BPL.

In an embodiment, the circuit elements of the backplane layer BPL may include circuit elements (e.g., the first, second, and third transistors T1, T2, and T3 and the capacitor Cst of FIG. 4) included in the pixel circuit PXC of each of the pixels PX. FIG. 7 illustrates the first transistor T1 included in each of the pixels PX as an example of the circuit elements included in the backplane layer BPL The backplane layer BPL may further include lines electrically connected to the pixels PX, the pads PD of the non-display area NDA, and the like.

The first transistor T1 may include an active layer ACT and a gate electrode GE disposed on a portion of the active layer ACT. In an embodiment, the first transistor T1 may further include at least one of a bottom electrode BML (or a light blocking layer), a source electrode SE, and a drain electrode DE.

The bottom electrode BML may be disposed on the barrier layer BRL (or the substrate SUB), and may be covered with the first insulating layer INS1. The bottom electrode BML may overlap the active layer ACT and the gate electrode GE. The first insulating layer INS1 may be disposed between the bottom electrode BML and the active layer ACT. The bottom electrode BML may overlap the entirety of a lower surface of the active layer ACT or a portion of a lower surface of the active layer ACT.

In an embodiment, the bottom electrode BML may be utilized as a back-gate electrode connected to one electrode of the first transistor T1 to adjust characteristics of the first transistor T1. As an example, the bottom electrode BML may be electrically connected to the source electrode SE of the first transistor T1 through at least one contact hole penetrating through the first insulating layer INS1 and the second insulating layer INS2.

The active layer ACT may be disposed on the first insulating layer INS1, and may be covered with the gate insulating layer GI and the second insulating layer INS2. The active layer ACT may include a channel region overlapping the gate electrode GE and a source region and a drain region located on different sides of the channel region. Conductivity of the source region and the drain region may be higher than conductivity of the channel region. For example, a carrier concentration (e.g., an electron concentration) of the source region and the drain region may be higher than a carrier concentration of the channel region.

In an embodiment, the active layer ACT may include an oxide semiconductor. For example, the active layer ACT may include an oxide semiconductor including at least one of indium (In), gallium (Ga), zinc (Zn), tin (Sn), and hafnium (Hf), or other oxide semiconductors. As an example, the active layer ACT may include at least one of zinc oxide (ZnO), zinc tin oxide (ZTO), indium zinc oxide (IZO), indium oxide (InO or In₂O₃), titanium oxide (TiO or TiO₂), indium gallium oxide (IGO), indium gallium zinc oxide (IGZO), indium gallium tin oxide (IGTO), indium zinc tin oxide (IZTO), and indium tin gallium zinc oxide (ITGZO), or other oxide semiconductors. However, embodiments are not limited thereto. For example, the active layer ACT may also be made of a semiconductor material (e.g., amorphous silicon or polysilicon) other than the oxide semiconductor.

The gate electrode GE may be disposed on the gate insulating layer GI, and may be covered with the second insulating layer INS2. The gate electrode GE may be disposed on a portion of the active layer ACT including the channel region.

The source electrode SE and the drain electrode DE may be disposed on the second insulating layer INS2, and may be covered with a third insulating layer INS3. The source electrode SE may be electrically connected to a portion (e.g., the source region) of the active layer ACT that does not overlap the gate electrode GE through at least one contact hole penetrating through the second insulating layer INS2. When the source region of the first transistor T1 is directly connected to another circuit element, a line, a connection pattern, a light emitting element ED, and the like, the source electrode SE may be omitted. The drain electrode DE may be electrically connected to another portion (e.g., the drain region) of the active layer ACT that does not overlap the gate electrode GE through at least one contact hole penetrating through the second insulating layer INS2. When the drain region of the first transistor T1 is directly connected to another circuit element, a line, a connection pattern, and the like, the drain electrode DE may be omitted.

Each of the bottom electrode BML, the gate electrode GE, the source electrode SE, and the drain electrode DE may include at least one conductive material and may have a single-layer or multilayer structure. For example, each of the bottom electrode BML, the gate electrode GE, the source electrode SE, and the drain electrode DE may be formed as a single-layer or multilayer metal layer including at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and other metals, alloys thereof, or other conductive materials. In an embodiment, conductive patterns disposed at a same layer in the backplane layer BPL may be simultaneously formed using the same conductive material and may have the same cross-sectional structure.

The first transistor T1 of each pixel PX may be electrically connected to the light emitting element ED of each pixel PX. For example, the first transistor T1 of the first pixel PX1 may be electrically connected to a first light emitting element ED1 disposed in the first emission area EA1, the first transistor T1 of the second pixel PX2 may be electrically connected to a second light emitting element ED2 disposed in the second emission area EA2, and the first transistor T1 of the third pixel PX3 may be electrically connected to a third light emitting element ED3 disposed in the third emission area EA3. As an example, the source electrode SE included in the first transistor T1 of the first pixel PX1 may be electrically connected to a first electrode AE of the first light emitting element ED1 through at least one via hole (or contact hole) penetrating through the third insulating layer INS3. Similarly, the source electrode SE included in the first transistor T1 of the second pixel PX2 may be electrically connected to a first electrode AE of the second light emitting element ED2 through at least one via hole (or contact hole) penetrating through the third insulating layer INS3, and the source electrode SE included in the first transistor T1 of the third pixel PX3 may be electrically connected to a first electrode AE of the third light emitting element ED3 through at least one via hole (or contact hole) penetrating through the third insulating layer INS3.

The light emitting element layer EDL may be disposed on the backplane layer BPL. For example, the light emitting element layer EDL may be disposed on the third insulating layer INS3.

The light emitting element layer EDL may include a light emitting element LD of each of the pixels PX. For example, the light emitting element layer EDL may include the pixel defining layer PDL defining the emission areas EA of the pixels PX and the light emitting elements ED disposed in the emission areas EA. In plan view, the pixel defining layer PDL may surround the light emitting element ED of each pixel PX.

Each light emitting element ED may include a first electrode AE disposed in each emission area EA and a light emitting layer OL and a second electrode CE that are sequentially disposed on the first electrode AE. One of the first electrode AE and the second electrode CE of the light emitting element ED may be an anode electrode, and the other of the first electrode AE and the second electrode CE of the light emitting element ED may be a cathode electrode. As an example, the first electrode AE may be an anode electrode, and the second electrode CE may be a cathode electrode.

In an embodiment, the first electrode AE of the light emitting element ED may be disposed in each emission area EA as separate units. For example, the first electrode AE of the first light emitting element ED1 may be disposed in the first emission area EA1 of the first pixel PX1, the first electrode AE of the second light emitting element ED2 may be disposed in the second emission area EA2 of the second pixel PX2, and the first electrode AE of the third light emitting element ED3 may be disposed in the third emission area EA3 of the third pixel PX3. The first electrode AE of the first light emitting element ED1, the first electrode AE of the second light emitting element ED2, and the first electrode AE of the third light emitting element ED3 may be separated from each other.

The first electrode AE of the light emitting element ED may be connected to at least one transistor T included in the corresponding pixel PX. For example, the first electrode AE of the first light emitting element ED1 may be electrically connected to the first transistor T1 of the first pixel PX1, the first electrode AE of the second light emitting element ED2 may be electrically connected to the first transistor T1 of the second pixel PX2, and the first electrode AE of the third light emitting element ED3 may be electrically connected to the first transistor T1 of the third pixel PX3.

In an embodiment, the display panel 100 may be a top emission-type display panel, and the first electrode AE of the light emitting element ED may include a metal layer including a metal such as Ag, Mg, Al, Pt, Pd, Au, Ni, Nd, Ir, or Cr. In an embodiment, the first electrode AE of the light emitting element ED may further include a metal oxide layer overlapping the metal layer. As an example, the first electrode AE of the light emitting element ED may have a double-layer structure of indium tin oxide (ITO)/Ag, Ag/ITO, ITO/Mg, or ITO/MgF or a triple-layer structure such as ITO/Ag/ITO.

The pixel defining layer PDL may be disposed on the first electrodes AE of the light emitting elements ED. For example, the pixel defining layer PDL may be disposed in the non-emission area NEA to cover edge portions of the first electrodes AE of the light emitting elements ED, and may include openings (e.g., the first openings OP1 of FIG. 5) exposing other portions of the first electrodes AE. The pixel defining layer PDL may overlap a bank BK of the light conversion layer CVL and a light blocking pattern LBP of the color filter unit 130 in the third direction DR3.

In an embodiment, the pixel defining layer PDL may include an organic insulating material. As an example, the pixel defining layer PDL may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB), but is not limited thereto.

In an embodiment, the pixel defining layer PDL may further include a light blocking material including a first colorant having a high optical density (OD). For example, the pixel defining layer PDL may include a black colorant such as a black pigment or a black dye (e.g., an inorganic black pigment such as carbon black or an organic black pigment such as perylene black) and may be an opaque pattern with a very high light blocking rate. Accordingly, lateral leaked light traveling toward a lateral direction of the light emitting elements ED in the light emitting element layer EDL may be effectively blocked.

The light emitting layer OL may be disposed on each first electrode AE. In an embodiment, the light emitting layer OL may be formed as a common layer continuously or entirely disposed over the display area DA including the emission areas EA and the non-emission area NEA.

In an embodiment, the light emitting layer OL may emit light of a third color, for example, blue light. However, embodiments are not limited thereto. For example, the light emitting layer OL may also emit light of another color, for example, white light.

The light emitting layer OL may be located only in the display area DA but is not limited thereto. For example, a portion of the light emitting layer OL may also be disposed in at least a portion of the non-display area NDA.

The light emitting layer OL of the light emitting element ED may include a high molecular material or a low molecular material. Light emitted from the light emitting layer OL may contribute to image display. The light emitting layer OL will be described in detail later.

The second electrode CE may be disposed on the light emitting layer OL. In an embodiment, the second electrode CE may be a common electrode shared by the light emitting elements ED of the pixels PX. As an example, the second electrode CE may be formed as a common layer continuously or entirely disposed over the display area DA including the emission areas EA and the non-emission area NEA.

In an embodiment, the display panel 100 may be a top emission-type display panel, and the second electrode CE may have semi-transmissive properties or transmissive properties. In an embodiment, the second electrode CE may include Ag, Mg, Cu, Al, Pt, Pd, Au, Ni, Nd, Ir, Cr, Li, Ca, LiF/Ca, LiF/Al, Mo, Ti or compounds or mixtures thereof such as a mixture of Ag and Mg, and may have semi-transmissive properties. In an embodiment, the second electrode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), or the like, and may have transmissive properties.

The first electrode AE, the light emitting layer OL, and the second electrode CE disposed in each emission area EA may constitute each light emitting element ED. For example, the first electrode AE, the light emitting layer OL, and the second electrode CE disposed in the first emission area EA1 may constitute the first light emitting element ED1 of the first pixel PX1. The first electrode AE, the light emitting layer OL, and the second electrode CE disposed in the second emission area EA2 may constitute the second light emitting element ED2 of the second pixel PX2. The first electrode AE, the light emitting layer OL, and the second electrode CE disposed in the third emission area EA3 may constitute the third light emitting element ED3 of the third pixel PX3.

In an embodiment, the light emitting elements ED of the pixels PX may emit light of the same color. As an example, the first light emitting element ED1, the second light emitting element ED2, and the third light emitting element ED3 may be blue organic light emitting diodes that emit blue light.

In an embodiment, the light emitting element layer EDL may further include a first capping layer CPL1 covering the second electrode CE of the light emitting elements ED. For example, the light emitting element layer EDL may further include a first capping layer CPL1 disposed on the second electrode CE and including at least one of an inorganic material or an organic material having light transmitting properties. As an example, the first capping layer CPL1 may be formed as an inorganic layer, formed as an organic layer, or formed as an organic layer including inorganic particles. The first capping layer CPL1 may improve viewing angle characteristics of the display panel 100 and improve external luminous efficiency.

The encapsulation layer TFE may be disposed on the light emitting element layer EDL. The encapsulation layer TFE may cover the light emitting element layer EDL in the display area DA and extend to the non-display area NDA to be in contact with the backplane layer BPL. The encapsulation layer TFE may block permeation of oxygen or moisture into the light emitting element layer EDL and alleviate an electrical or physical shock to the backplane layer BPL and the light emitting element layer EDL. In an embodiment, the encapsulation layer TFE may be a thin film encapsulation layer including a first encapsulation layer ENL1, a second encapsulation layer ENL2, and a third encapsulation layer ENL3 that are sequentially disposed on the light emitting element layer EDL.

Each of the first encapsulation layer TFE1 and the third encapsulation layer TFE3 may be an inorganic encapsulation layer including an inorganic material. As an example, each of the first encapsulation layer TFE1 and the third encapsulation layer TFE3 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, lithium fluoride, or the like.

The second encapsulation layer TFE2 may be an organic encapsulation layer including an organic material. As an example, the second encapsulation layer TFE2 may include an acrylic resin, a methacrylic resin, polyisoprene, a vinyl-based resin, an epoxy-based resin, a urethane-based resin, a cellulose-based resin, a perylene-based resin, or the like.

The light conversion layer CVL may be disposed on the light emitting element layer EDL. For example, the light conversion layer CVL may be disposed on the encapsulation layer TFE. In an embodiment, the light conversion layer CVL may be directly formed on the encapsulation layer TFE but is not limited thereto. For example, in an embodiment, the light conversion layer CVL may be formed on the color filter unit 130 and disposed to face the encapsulation layer TFE.

The light conversion layer CVL may include light conversion members CV (e.g., wavelength conversion members and/or light transmitting members) disposed in the light transmitting areas TA. For example, the light conversion layer CVL may include the bank BK defining the light transmitting areas TA corresponding to the emission areas EA and the light conversion members CV disposed in the light transmitting areas TA. In an embodiment, the light conversion layer CVL may further include a second capping layer CPL2 covering the light conversion members CV and the bank BK.

The bank BK may be mainly disposed in the light blocking area NTA to surround the light conversion members CV. The light blocking area NTA is an area overlapping at least a portion of the non-emission area NEA, and the bank BK may overlap the pixel defining layer PDL. For example, the bank BK may be disposed on at least a portion of the pixel defining layer PDL. The bank BK may include openings (e.g., the second openings OP2 of FIG. 6) exposing the light conversion members CV. The bank BK may be formed at a thickness enough to provide spaces in which the light conversion members CV are formed.

In an embodiment, based on a top surface of the bank BK facing a front direction of the display panel 100, the bank BK may have a width smaller than a width of the pixel defining layer PDL. For example, the bank BK may be formed as a pattern having a smaller width than the pixel defining layer PDL. As a width of the bank BK is reduced or minimized, areas of the light transmitting areas TA may increase. Accordingly, an aperture ratio of the light conversion layer CVL (or the display device 1 including the light conversion layer CVL) may be increased.

In an embodiment, the bank BK may include an organic insulating material. As an example, the bank BK may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB), but is not limited thereto. In an embodiment, the bank BK may include a photosensitive material, for example, a photocurable material such as a negative photoresist, and may be formed by a photolithography process. In an embodiment, the bank BK may include at least one of the materials included in the pixel defining layer PDL but is not limited thereto.

In an embodiment, the bank BK may further include a light blocking material including a second colorant. As an example, the bank BK may include a second colorant suitable for blocking light (e.g., blue light) of a wavelength band corresponding to the light generated from the light emitting elements ED.

In an embodiment, an optical density of the bank BK may be lower than the optical density of the pixel defining layer PDL. For example, the second colorant included in the bank BK may be a colored colorant that may have a lower optical density than the first colorant included in the pixel defining layer PDL and appropriately block light of a wavelength band generated from the light emitting elements ED.

In an embodiment, the second colorant may be a purple colorant. The bank BK may include the second colorant alone or may further include a colored colorant different from the second colorant. As an example, the bank BK may include a purple colorant only or may include a purple colorant and another colored colorant (e.g., at least one of a yellow colorant, an orange colorant, and a blue colorant).

When the optical density of the bank BK is lower than the optical density of the pixel defining layer PDL, the bank BK may be more precisely formed in a process of forming a desired pattern using light, such as a photolithography process. For example, when the optical density of the bank BK is lower than the optical density of the pixel defining layer PDL, the bank BK may be formed as a fine pattern having a smaller width. Accordingly, by appropriately and/or easily reducing the width of the bank BK, it is possible to increase the aperture ratio of the light conversion layer CVL. In addition, the bank BK includes the light blocking material, and accordingly, may appropriately block light traveling in a lateral direction toward an adjacent pixel PX in the light conversion layer CVL.

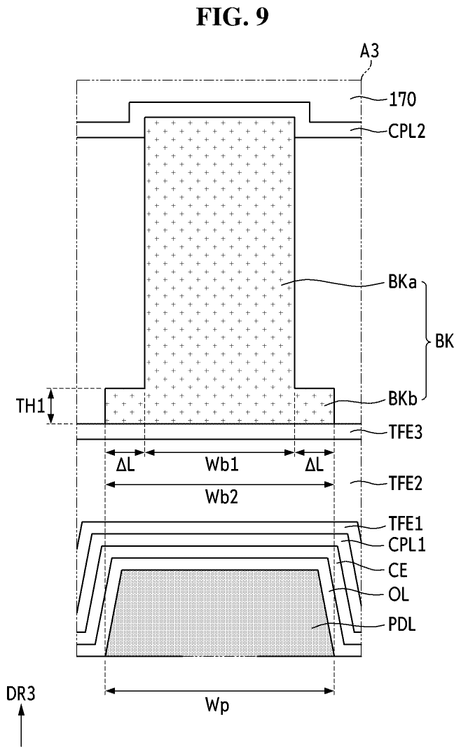

In an embodiment, the bank BK may include extending portions (e.g., extending portions BKb of FIG. 9) extending in a horizontal direction at a lower end portion. For example, the bank BK may include wing-shaped extending portions extending in a circumferential direction at the lower end portion below a middle height. As an example, the bank BK may have a screw-shaped cross section between adjacent light transmitting areas TA. A width of a bottom surface of the bank BK including the lower end portion may be greater than a width of the light blocking area NTA.

The bank BK partially extends at the lower end portion, and accordingly, may appropriately block lateral light traveling toward the light transmitting area TA of the adjacent pixel PX among the light emitted from the light emitting element ED of each of the pixels PX. For example, as illustrated by a dotted arrow in FIG. 7, at least some of lateral light LL traveling toward the second light transmitting area TA2 of the second pixel PX2 among the light emitted from the third light emitting element ED3 of the third pixel PX3 may be absorbed or blocked by the extending portion of the bank BK. A shape of the bank BK according to an embodiment will be described in detail later.

The light conversion members CV may include a first light conversion member CV1 (also referred to as a “first light transmitting member”) disposed in the first light transmitting area TA1, a second light conversion member CV2 (also referred to as a “second light transmitting member”) disposed in the second light transmitting area TA2, and a third light conversion member CV3 (also referred to as a “third light transmitting member”) disposed in the third light transmitting area TA3.

Each of the light conversion members CV may include a base resin BRS. The base resin BRS may include a light transmitting organic material. For example, the base resin BRS may include an epoxy-based resin, an acrylic resin, a cardo-based resin, an imide-based resin, or the like. In an embodiment, each of the light conversion members CV may further include light diffusing agents SCT such as titanium oxide (TiO₂), zirconium oxide (ZrO₂), aluminum oxide (Al₂O₃), indium oxide (In₂O₃), zinc oxide (ZnO), or tin oxide (SnO₂).

The first light conversion member CV1 may be disposed on the first light emitting element ED1. The first light conversion member CV1 may convert light emitted from the first light emitting element ED1 into light of a first color. For example, the first light emitting element ED1 may emit light of a third color (e.g., blue light), and the first light conversion member CV1 may convert the light of the third color incident from the first light emitting element ED1 into the light of the first color (e.g., red light). To this end, the first light conversion member CV1 may include first wavelength shifters WS1 converting the light of the third color into the light of the first color. For example, the first light conversion member CV1 may include the first wavelength shifters WS1 dispersed in the base resin BRS. The first wavelength shifter WS1 may convert the light of the third color incident from the first light emitting element ED1 into the light of the first color. The first wavelength shifter WS1 may be a quantum dot (e.g., a red quantum dot), a quantum rod, a fluorescent material, or a phosphorescent material.

The light of the first color converted by the first light conversion member CV1 may be transmitted through a first color filter CF1 or the like and emitted to an upper portion of the display panel 100. For example, emitted light (e.g., emitted light of the first pixel PX1) emitted from the first emission area EA1, transmitted through the first light transmitting area TA1, and emitted to the outside may be the light of the first color (e.g., the red light).

The second light conversion member CV2 may be disposed on the second light emitting element ED2. The second light conversion member CV2 may convert light emitted from the second light emitting element ED2 into light of a second color. For example, the second light emitting element ED2 may emit light of a third color (e.g., blue light), and the second light conversion member CV2 may convert the light of the third color incident from the second light emitting element ED2 into the light of the second color (e.g., green light). To this end, the second light conversion member CV2 may include second wavelength shifters WS2 converting the light of the third color into the light of the second color. For example, the second light conversion member CV2 may include the second wavelength shifters WS2 dispersed in the base resin BRS. The second wavelength shifter WS2 may convert the light of the third color incident from the second light emitting element ED2 into the light of the second color. The second wavelength shifter WS2 may be a quantum dot (e.g., a green quantum dot), a quantum rod, a fluorescent material, or a phosphorescent material.

The light of the second color converted by the second light conversion member CV2 may be transmitted through a second color filter CF2 or the like and emitted to an upper portion of the display panel 100. For example, emitted light (e.g., emitted light of the second pixel PX2) emitted from the second emission area EA2, transmitted through the second light transmitting area TA2, and emitted to the outside may be the light of the second color (e.g., the green light).

The third light conversion member CV3 may be disposed on the third light emitting element ED3. The third light conversion member CV3 may transmit light emitted from the third light emitting element ED3. For example, the third light conversion member CV3 may not include wavelength shifters and may diffuse and/or transmit light of a third color incident from the third light emitting element ED3.

The light of the third color transmitted through the third light conversion member CV3 may be transmitted through a third color filter CF3 or the like and emitted to an upper portion of the display panel 100. For example, emitted light (e.g., emitted light of the third pixel PX3) emitted from the third emission area EA3, transmitted through the third light transmitting area TA3, and emitted to the outside may be the light of the third color (e.g., the blue light).

The second capping layer CPL2 may be disposed on the light conversion members CV and the bank BK. The second capping layer CPL2 may include a material (e.g., an inorganic material) suitable for protecting the light conversion members CV and the bank BK from moisture, foreign substances, or the like.

The color filter unit 130 may be disposed on the light emitting unit 110. In an embodiment, the light emitting unit 110 and the color filter unit 130 may be manufactured individually and coupled to each other so as to face each other, and the filler 170 may be disposed between the light emitting unit 110 and the color filter unit 130.

The filler 170 may fill a space between the light emitting unit 110 including the light conversion layer CVL and the color filter unit 130. In an embodiment, the filler 170 may be made of a material having a very low extinction coefficient. For example, the filler 170 may be made of a material having an extinction coefficient of substantially 0. A refractive index and the extinction coefficient are correlated to each other, and as the refractive index decreases, the extinction coefficient may also decrease. In addition, when the refractive index is 1.7 or less, the extinction coefficient may substantially converge to 0. In an embodiment, the filler 170 may be made of a material having a refractive index of 1.7 or less, and accordingly, may prevent or minimize a phenomenon in which the light emitted from the light emitting unit 110 is absorbed while being transmitted through the filler 170. In an embodiment, the filler 170 may be made of an organic material having a refractive index of 1.4 to 1.6.

The color filter unit 130 may include an encapsulation substrate ENC and color filters CF disposed on one surface of the encapsulation substrate ENC. For example, the color filters CF may be disposed on a lower surface of the encapsulation substrate ENC facing the light emitting unit 110. In some embodiments, when the color filters CF are directly disposed or formed on the light emitting unit 110, the encapsulation substrate ENC, the filler 170, the sealant 150, and the like, may be omitted. In an embodiment, the color filter unit 130 may further include a low refraction layer LRL (or an overcoat layer) disposed on one surface of the encapsulation substrate ENC and covering the color filters CF and a protective layer AF disposed on the other surface (e.g., an upper surface) of the encapsulation substrate ENC.

The encapsulation substrate ENC may be disposed on the light emitting unit 110. For example, the encapsulation substrate ENC may be an upper substrate or a window of the display panel 100. The encapsulation substrate ENC may be a rigid or flexible substrate or film. As an example, the encapsulation substrate ENC may be made of rigid encapsulation glass or be formed as a flexible substrate including plastic, a high-strength polymer, or the like.

The color filters CF may include the first color filter CF1 disposed in the first light transmitting area TA1, the second color filter CF2 disposed in the second light transmitting area TA2, and the third color filter CF3 disposed in the third light transmitting area TA3.

The first color filter CF1 may be disposed on the first light conversion member CV1. The first color filter CF1 may transmit the light of the first color and absorb or block the light of the third color. For example, the first color filter CF1 may transmit the light of the first color that is converted by the first light conversion member CV1 among the light of the third color emitted from the first light emitting element ED1, and absorb or block the light of the third color that is not converted by the first light conversion member CV1 among the light of the third color emitted from the first light emitting element ED1. Accordingly, the light of the first color may be emitted from the first light transmitting area TA1. As an example, the first color filter CF1 may be a red color filter, and the red light may be emitted from the first light transmitting area TA1.

The second color filter CF2 may be disposed on the second light conversion member CV2. The second color filter CF2 may transmit the light of the second color and absorb or block the light of the third color. For example, the second color filter CF2 may transmit the light of the second color that is converted by the second light conversion member CV2 among the light of the third color emitted from the second light emitting element ED2, and absorb or block the light of the third color that is not converted by the second light conversion member CV2 among the light of the third color emitted from the second light emitting element ED2. Accordingly, the light of the second color may be emitted from the second light transmitting area TA2. As an example, the second color filter CF2 may be a green color filter, and the green light may be emitted from the second light transmitting area TA2.

The third color filter CF3 may be disposed on the third light conversion member CV3. The third color filter CF3 may transmit the light of the third color. For example, the third color filter CF3 may transmit the light of the third color emitted from the third light emitting element ED3 and passing through the third light conversion member CV3. Accordingly, the light of the third color may be emitted from the third light transmitting area TA3. As an example, the third color filter CF3 may be a blue color filter, and the blue light may be emitted from the third light transmitting area TA3.

The color filter unit 130 may further include the light blocking pattern LBP disposed in the light blocking area NTA. In an embodiment, the light blocking pattern LBP may include a portion of each of the first color filter CF1, the second color filter CF2, and the third color filter CF3. For example, the first color filter CF1, the second color filter CF2, and the third color filter CF3 may overlap each other in the light blocking area NTA to form the light blocking pattern LBP. As an example, the first color filter CF1, the second color filter CF2, and the third color filter CF3 disposed in the respective light transmitting areas TA may extend to the light blocking area NTA to overlap each other, and accordingly, may form the light blocking pattern LBP in the light blocking area NTA. However, embodiments are not limited thereto, and the color filter unit 130 may further include a separate light blocking pattern (e.g., a black matrix) disposed in the light blocking area NTA.

The light blocking pattern LBP may overlap at least a portion of the bank BK. As an example, the light blocking pattern LBP may overlap a partition wall portion (e.g., a partition wall portion BKa of FIG. 9) of the bank BK.

The low refraction layer LRL may cover one surfaces of the color filters CF facing the light emitting unit 110. In an embodiment, the low refraction layer LRL may have a lower refractive index than the light conversion members CV of the light conversion layer CVL. Accordingly, total reflection of light traveling from the light conversion members CV to the low refraction layer LRL may be induced, such that the light may be recycled and light efficiency of the pixels PX may be increased.

In an embodiment, a refractive index of the low refraction layer LRL may be 1.3 or less. When the refractive index of the low refraction layer LRL is 1.3 or less, a difference in refractive index between the light conversion members CV and the low refraction layer LRL is great, such that the total reflection of the light may sufficiently occur. In addition, the low refraction layer LRL may compensate for a step due to the color filters CF to planarize a surface of the color filter unit 130.

The protective layer AF may be disposed on a light emitting surface (e.g., an upper surface) of the display panel 100. The protective layer AF may include a functional layer protecting the display panel 100 or providing various functions. As an example, the protective layer AF may include at least one protective film or coating layer having anti-reflection, anti-fingerprint, anti-scratch, and/or blue light blocking functions.

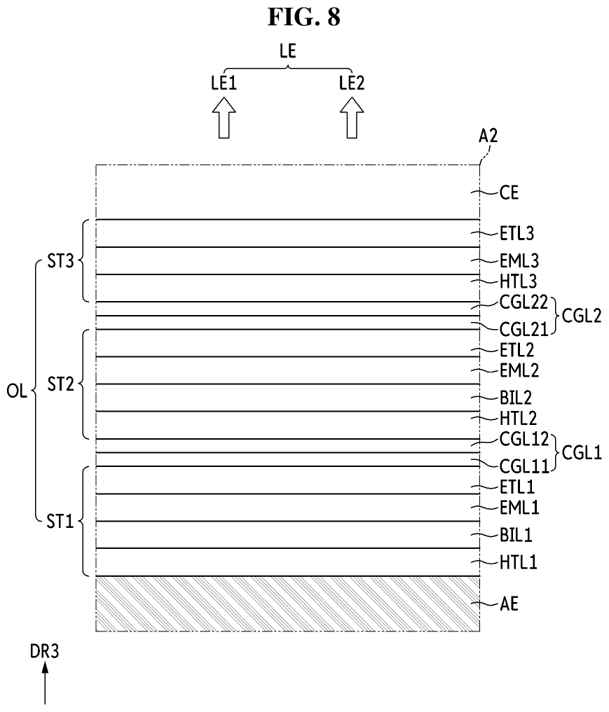

FIG. 8 is an enlarged view of area A2 of FIG. 7. For example, FIG. 8 illustrates the light emitting layer OL according to an embodiment in detail.

Referring to FIGS. 7 and 8, the light emitting layer OL may have a structure in which a plurality of light emitting material layers overlap each other, for example, a tandem structure. In an embodiment, the light emitting layer OL may include a first stack ST1 including a first light emitting material layer EML1, a second stack ST2 located on the first stack ST1 and including a second light emitting material layer EML2, a third stack ST3 located on the second stack ST2 and including a third light emitting material layer EML3, a first charge generating layer CGL1 located between the first stack ST1 and the second stack ST2, and a second charge generating layer CGL2 located between the second stack ST2 and the third stack ST3. The first stack ST1, the second stack ST2, and the third stack ST3 may overlap each other.

The first light emitting material layer EML1, the second light emitting material layer EML2, and the third light emitting material layer EML3 may overlap each other. In an embodiment, the first light emitting material layer EML1, the second light emitting material layer EML2, and the third light emitting material layer EML3 may all emit light of a third color, for example, blue light. As an example, each of the first light emitting material layer EML1, the second light emitting material layer EML2, and the third light emitting material layer EML3 may be a blue light emitting layer and may include an organic material.

In an embodiment, at least one of the first light emitting material layer EML1, the second light emitting material layer EML2, and the third light emitting material layer EML3 may emit first blue light having a first peak wavelength, and at least another of the first light emitting material layer EML1, the second light emitting material layer EML2, and the third light emitting material layer EML3 may emit second blue light having a second peak wavelength different from the first peak wavelength. In an embodiment, at least one of the first light emitting material layer EML1, the second light emitting material layer EML2, and the third light emitting material layer EML3 may emit first blue light having a first peak wavelength, and the others of the first light emitting material layer EML1, the second light emitting material layer EML2, and the third light emitting material layer EML3 may emit second blue light having a second peak wavelength. For example, emitted light LE finally emitted from the light emitting layer OL may be mixed light in which a first component LE1 and a second component LE2 are mixed with each other, the first component LE1 may be the first blue light having the first peak wavelength, and the second component LE2 may be the second blue light having the second peak wavelength.

In an embodiment, a range of one of the first peak wavelength and the second peak wavelength may be 440 nm or more and less than 460 nm, and a range of the other of the first peak wavelength and the second peak wavelength may be 460 nm or more and 480 nm or less. However, the range of the first peak wavelength and the range of the second peak wavelength are not limited thereto. For example, both the range of the first peak wavelength and the range of the second peak wavelength may also include 460 nm. In an embodiment, any one of the first blue light and the second blue light may be light of a deep blue color, and the other of the first blue light and the second blue light may be light of a sky blue color.

In an embodiment, the emitted light LE emitted from the light emitting layer OL may be blue light and may include a long-wavelength component and a short-wavelength component. Accordingly, the light emitting layer OL may emit blue light having a broader emission peak as the emitted light LE. Therefore, there is an advantage that color visibility at a side viewing angle may be improved compared to a display panel 100 using other light emitting elements emitting blue light having a sharper emission peak.

In an embodiment, each of the first light emitting material layer EML1, the second light emitting material layer EML2, and the third light emitting material layer EML3 may include a host and a dopant. The host may be tris(8-hydroxyquinolino)aluminum (Alq₃), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyryl arylene (DSA), 4,4′-bis(9-carbazolyl)-2,2″-dimethyl-biphenyl (CDBP), 2-methyl-9,10-bis(naphthalen-2-yl)anthracene (MADN), or the like, but is not limited thereto.

In an embodiment, each of the first light emitting material layer EML1, the second light emitting material layer EML2, and the third light emitting material layer EML3 may include a fluorescent material including any one selected from the group consisting of spiro-DPVBi, spiro-6P, distyryl-benzene (DSB), distyryl-arylene (DSA), a polyfluorene (PFO)-based polymer, and a poly(p-phenylene vinylene) (PPV)-based polymer. In an embodiment, each of the first light emitting material layer EML1, the second light emitting material layer EML2, and the third light emitting material layer EML3 may include a phosphorescent material including an organometallic complex such as (4,6-F2ppy)2Irpic. The first light emitting material layer EML1, the second light emitting material layer EML2, and the third light emitting material layer EML3 may include materials other than the exemplified materials.

As described above, at least one of the first light emitting material layer EML1, the second light emitting material layer EML2, and the third light emitting material layer EML3 emits blue light of a wavelength band different from that of at least another of the first light emitting material layer EML1, the second light emitting material layer EML2, and the third light emitting material layer EML3. In an embodiment, in order to emit blue light of different wavelength bands, the first light emitting material layer EML1, the second light emitting material layer EML2, and the third light emitting material layer EML3 may include the same material and a method of adjusting a resonance distance may be used. In another example, in order to emit blue light of different wavelength bands, at least one of the first light emitting material layer EML1, the second light emitting material layer EML2, and the third light emitting material layer EML3 and at least another of the first light emitting material layer EML1, the second light emitting material layer EML2, and the third light emitting material layer EML3 may include different materials.

However, embodiments are not limited thereto. For example, the blue light emitted by each of the first light emitting material layer EML1, the second light emitting material layer EML2, and the third light emitting material layer EML3 may have a peak wavelength of 440 nm to 480 nm, and the first light emitting material layer EML1, the second light emitting material layer EML2, and the third light emitting material layer EML3 may be made of the same material.

In an embodiment, at least one of the first light emitting material layer EML1, the second light emitting material layer EML2, and the third light emitting material layer EML3 may emit first blue light having a first peak wavelength, another of the first light emitting material layer EML1, the second light emitting material layer EML2, and the third light emitting material layer EML3 may emit second blue light having a second peak wavelength different from the first peak wavelength, and the other of the first light emitting material layer EML1, the second light emitting material layer EML2, and the third light emitting material layer EML3 may emit third blue light having a third peak wavelength different from the first peak wavelength and the second peak wavelength.

In an embodiment, a range of any one of the first peak wavelength, the second peak wavelength, and the third peak wavelength may be 440 nm or more and less than 460 nm. A range of another of the first peak wavelength, the second peak wavelength, and the third peak wavelength may be 460 nm or more and less than 470 nm, and a range of the other of the first peak wavelength, the second peak wavelength, and the third peak wavelength may be 470 nm or more and 480 nm or less.

In an embodiment, the emitted light LE emitted from the light emitting layer OL may be blue light, and may include a long-wavelength component, a mid-wavelength component, and a short-wavelength component. Accordingly, the light emitting layer OL may emit blue light having a broader emission peak as the emitted light LE and may improve color visibility at a side viewing angle of the display panel 100.

The light emitting element ED having the tandem structure described above has an advantage that light efficiency may be increased and an advantage that a lifespan of the display device 1 may be increased, compared to a light emitting element having a non-tandem structure.

In an embodiment, at least one of the first light emitting material layer EML1, the second light emitting material layer EML2, and the third light emitting material layer EML3 may emit the light of the third color, for example, the blue light, and at least another of the first light emitting material layer EML1, the second light emitting material layer EML2, and the third light emitting material layer EML3 may emit the light of the second color, for example, the green light. A range of a peak wavelength of the blue light emitted by at least one of the first light emitting material layer EML1, the second light emitting material layer EML2, and the third light emitting material layer EML3 may be 440 nm or more to 480 nm or less or 460 nm or more to 480 nm or less. A range of a peak wavelength of the green light emitted by at least another of the first light emitting material layer EML1, the second light emitting material layer EML2, and the third light emitting material layer EML3 may be 510 nm to 550 nm.

As an example, any one of the first light emitting material layer EML1, the second light emitting material layer EML2, and the third light emitting material layer EML3 may be a green light emitting layer emitting the green light, and the others of the first light emitting material layer EML1, the second light emitting material layer EML2, and the third light emitting material layer EML3 may be blue light emitting layers emitting the blue light. When the others of the first light emitting material layer EML1, the second light emitting material layer EML2, and the third light emitting material layer EML3 are the blue light emitting layers, ranges of peak wavelengths of the blue light emitted by the two blue light emitting layers may be the same as or different from each other.

In an embodiment, the emitted light LE emitted from the light emitting layer OL may be mixed light in which a first component LE1, which is blue light, and a second component LE2, which is green light, are mixed with each other. For example, when the first component LE1 is light of a deep blue color and the second component LE2 is green light, the emitted light LE may be light of a sky blue color. Similar to the above-described embodiments, the emitted light LE emitted from the light emitting layer OL is mixed light of the blue light and the green light and includes a long-wavelength component and a short-wavelength component. Accordingly, the light emitting layer OL may emit blue light having a broader emission peak as the emitted light LE and may improve color visibility at a side viewing angle. In addition, when the second component LE2 of the emitted light LE is the green light, a green light component of the light provided from the display device 1 to the outside may be complemented, and accordingly, color reproducibility of the display device 1 may be improved.

In an embodiment, the green light emitting layer of the first light emitting material layer EML1, the second light emitting material layer EML2, and the third light emitting material layer EML3 may include a host and a dopant. The host of the green light emitting layer may be tris(8-hydroxyquinolino)aluminum (Alq₃), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyryl arylene (DSA), 4,4′-bis(9-carbazolyl)-2,2″-dimethyl-biphenyl (CDBP), or 2-methyl-9,10-bis(naphthalen-2-yl)anthracene (MADN), but is not limited thereto. The dopant of the green light emitting layer is a fluorescent material including tris-(8-hydroyquinolato) aluminum(III) (Alq₃) or a phosphorescent material, and may be fac tris(2-phenylpyridine)iridium (Ir(ppy)₃), bis(2-phenylpyridine) (acetylacetonate)iridium(III) (Ir(ppy)₂(acac)), tris[2-(p-tolyl)pyridine]iridium(III) (Ir(mppy)₃), or the like, but is not limited thereto.

The first charge generating layer CGL1 may be located between the first stack ST1 and the second stack ST2. The first charge generating layer CGL1 may inject charges into each light emitting layer OL. The first charge generating layer CGL1 may adjust charge balance between the first stack ST1 and the second stack ST2. The first charge generating layer CGL1 may include an n-type charge generating layer CGL11 and a p-type charge generating layer CGL12. The p-type charge generating layer CGL12 may be disposed on the n-type charge generating layer CGL11 and may be located between the n-type charge generating layer CGL11 and the second stack ST2.

The first charge generating layer CGL1 may have a structure in which the n-type charge generating layer CGL11 and the p-type charge generating layer CGL12 are in contact with each other. The n-type charge generating layer CGL11 may be more adjacent to the first electrode AE of the light emitting element ED than the p-type charge generating layer CGL12 is. The p-type charge generating layer CGL12 may be more adjacent to the second electrode CE of the light emitting element ED than the n-type charge generating layer CGL11 is. The n-type charge generating layer CGL11 may supply electrons to the first light emitting material layer EML1 adjacent to the first electrode AE, and the p-type charge generating layer CGL12 may supply holes to the second light emitting material layer EML2 included in the second stack ST2. The first charge generating layer CGL1 may be disposed between the first stack ST1 and the second stack ST2 and provide charges to the light emitting material layers of the first and second stacks to increase luminous efficiency of the light emitting element ED and reduce a driving voltage of the light emitting element ED.

The first stack ST1 may be located on the first electrodes AE of the light emitting elements ED disposed in the emission areas EA. The first stack ST1 may further include a first hole transporting layer HTL1, a first electron blocking layer BIL1, and a first electron transporting layer ETL1.

The first hole transporting layer HTL1 may be located on the first electrodes AE of the light emitting elements ED. The first hole transporting layer HTL1 may facilitate transport of holes and include a hole transporting material. The hole transporting material may include carbazole-based derivatives such as N-phenylcarbazole and polyvinylcarbazole, fluorene-based derivatives, triphenylamine-based derivatives such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4.4′-cyclohexylidene bis[N,N-bis(4-methylphenyl)benzenamine] (TAPC), and the like, but is not limited thereto.

The first electron blocking layer BIL1 may be located on the first hole transporting layer HTL1. For example, the first electron blocking layer BIL1 may be located between the first hole transporting layer HTL1 and the first light emitting material layer EML1. The first electron blocking layer BIL1 may include a hole transporting material and a metal or a metal compound so as to prevent electrons generated in the first light emitting material layer EML1 from crossing over into the first hole transporting layer HTL1. In an embodiment, each of the first hole transporting layer HTL1 and the first electron blocking layer BIL1 may also be formed as a single layer in which the respective materials are mixed with each other.

The first electron transporting layer ETL1 may be located on the first light emitting material layer EML1. For example, the first electron transporting layer ETL1 may be located between the first charge generating layer CGL1 and the first light emitting material layer EML1. In an embodiment, the first electron transporting layer ETL1 may include an electron transporting material such as tris(8-hydroxyquinolinato)aluminum (Alq₃), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate (Bebq2), 9,10-di(naphthalene-2-yl)anthracene (ADN), and mixtures thereof, but the electron transporting material is not limited thereto.

The second stack ST2 may be located on the first charge generating layer CGL1. The second stack ST2 may further include a second hole transporting layer HTL2, a second electron blocking layer BIL2, and a second electron transporting layer ETL2.

The second hole transporting layer HTL2 may be located on the first charge generating layer CGL1. The second hole transporting layer HTL2 may be made of the same material as the first hole transporting layer HTL1 or may include one or more materials selected from the materials exemplified as the material included in the first hole transporting layer HTL1. The second hole transporting layer HTL2 may be formed as a single layer or multiple layers.

The second electron blocking layer BIL2 may be located on the second hole transporting layer HTL2. For example, the second electron blocking layer BIL2 may be located between the second hole transporting layer HTL2 and the second light emitting material layer EML2. The second electron blocking layer BIL2 may be made of the same material as the first electron blocking layer BIL1 and may have the same structure as the first electron blocking layer BIL1 or may include one or more materials selected from the materials exemplified as the material included in the first electron blocking layer BIL1.

The second electron transporting layer ETL2 may be located on the second light emitting material layer EML2. For example, the second electron transporting layer ETL2 may be located between the second charge generating layer CGL2 and the second light emitting material layer EML2. The second electron transporting layer ETL2 may be made of the same material as the first electron transporting layer ETL1 and may have the same structure as the first electron transporting layer ETL1 or may include one or more materials selected from the materials exemplified as the material included in the first electron transporting layer ETL1. The second electron transporting layer ETL2 may be formed as a single layer or multiple layers.

The second charge generating layer CGL2 may be located on the second stack ST2. For example, the second charge generating layer CGL2 may be located between the second stack ST2 and the third stack ST3. The second charge generating layer CGL2 may have the same structure as the first charge generating layer CGL1. For example, the second charge generating layer CGL2 may include an n-type charge generating layer CGL21 and a p-type charge generating layer CGL22. The p-type charge generating layer CGL22 may be disposed on the n-type charge generating layer CGL21.

The second charge generating layer CGL2 may have a structure in which the n-type charge generating layer CGL21 and the p-type charge generating layer CGL22 are in contact with each other. The first charge generating layer CGL1 and the second charge generating layer CGL2 may be made of the same material or different materials.

The third stack ST3 may be located on the second charge generating layer CGL2. The third stack ST3 may further include a third hole transporting layer HTL3 and a third electron transporting layer ETL3.

The third hole transporting layer HTL3 may be located on the second charge generating layer CGL2. The third hole transporting layer HTL3 may be made of the same material as the first hole transporting layer HTL1 or may include one or more materials selected from the materials exemplified as the material included in the first hole transporting layer HTL1. The third hole transporting layer HTL3 may be formed as a single layer or multiple layers. When the third hole transporting layer HTL3 is formed as the multiple layers, the respective layers may include different materials.

The third electron transporting layer ETL3 may be located on the third light emitting material layer EML3. For example, the third electron transporting layer ETL3 may be located between the second electrode CE of the light emitting element ED and the third light emitting material layer EML3. The third electron transporting layer ETL3 may be made of the same material as the first electron transporting layer ETL1 and may have the same structure as the first electron transporting layer ETL1 or may include one or more materials selected from the materials exemplified as the material included in the first electron transporting layer ETL1. The third electron transporting layer ETL3 may be formed as a single layer or multiple layers. When the third electron transporting layer ETL3 is formed as the multiple layers, the respective layers may include different materials.

Although not illustrated in FIG. 8, a hole injection layer may be further located between the first electrode AE of each of the light emitting elements ED and the first stack ST1, between the first charge generating layer CGL1 and the second stack ST2, or between the second charge generating layer CGL2 and the third stack ST3. The hole injection layer may serve to more smoothly inject holes into the first light emitting material layer EML1, the second light emitting material layer EML2, and the third light emitting material layer EML3. In an embodiment, the hole injection layer may be made of one or more selected from the group consisting of cupper phthalocyanine (CuPc), poly(3,4)-ethylenedioxythiophene (PEDOT), polyaniline (PANI), and N,N-dinaphthyl-N,N′-diphenyl benzidine (NPD), but is not limited thereto.

In addition, an electron injection layer may be further located between the first stack ST1 and the first charge generating layer CGL1, between the second stack ST2 and the second charge generating layer CGL2, or between the third electron transporting layer ETL3 and the second electrode CE of the light emitting elements ED. The electron injection layer may serve to smoothly inject electrons and may be made of tris(8-hydroxyquinolino)aluminum (Alq₃), PBD, TAZ, spiro-PBD, BAlq, or SAlq, but is not limited thereto. In addition, the electron injection layer may include a metal halide compound, for example, one or more selected from the group consisting of MgF₂, LiF, NaF, KF, RbF, CsF, FrF, LiI, NaI, KI, RbI, CsI, FrI, and CaF₂, but is not limited thereto. In addition, the electron injection layer may include a lanthanum-based material such as Yb, Sm, or Eu. In an example, the electron injection layer may include both a metal halide material and a lanthanum-based material such as RbI:Yb or KI:Yb. When the electron injection layer includes both the metal halide material and the lanthanum-based material, the electron injection layer may be formed by co-depositing the metal halide material and the lanthanum-based material.

In an embodiment, the light emitting layer OL may not include a red light emitting material layer, and accordingly, may not emit the light of the third color such as the red light. For example, the emitted light LE may not include a light component having a peak wavelength in the range of 610 nm to about 650 nm, and may include only a light component having a peak wavelength in the range of 440 nm to 550 nm.

FIG. 9 is an enlarged view of area A3 of FIG. 7. For example, FIG. 9 is an enlarged view illustrating the bank BK according to an embodiment in detail, and illustrates a cross section of a portion of the bank BK disposed between the first light transmitting area TA1 and the second light transmitting area TA2.

Referring to FIGS. 7 to 9, the bank BK may include a partition wall portion BKa and extending portions BKb. The extending portions BKb are portions extending from a lower end portion of the partition wall portion BKa, and the partition wall portion BKa and the extending portions BKb of the bank BK may be formed integrally with each other.

The partition wall portion BKa is a main portion (e.g., a core portion) of the bank BK defining or partitioning the light transmitting areas TA, and most of the bank BK may correspond to the partition wall portion BKa. For example, the remaining portion of the bank BK excluding the extending portions BKb may correspond to the partition wall portion BKa of the bank BK.

The partition wall portion BKa may have a width Wb1 smaller than a width Wp of the pixel defining layer PDL, and may overlap a central portion of the pixel defining layer PDL. As an example, the partition wall portion BKa may be disposed on a top surface of the pixel defining layer PDL, and in plan view, an edge of the partition wall portion BKa may be located inside the pixel defining layer PDL.

For example, the partition wall portion BKa may include the second openings OP2 exposing the respective emission areas EA and the perimeters of the emission areas EA, as illustrated in FIG. 6. At an edge portion of each of the second openings OP2, a portion of the pixel defining layer PDL located at the perimeter of each of the emission areas EA may be exposed. In plan view, the partition wall portion BKa may surround a portion of the pixel defining layer PDL in contact with each emission area EA.

In an embodiment, the bank BK may include a photocurable material, and may have a lower optical density than the pixel defining layer PDL. Accordingly, even when the partition wall portion BKa of the bank BK has the width Wb1 smaller than that of the pixel defining layer PDL, the bank BK may be stably and/or easily formed by a process utilizing light, such as a photolithography process.

For example, the pixel defining layer PDL may include a black colorant having a high optical density, and may be formed at the width Wp of approximately 10 μm or more in consideration of easiness, stability, or the like, of a process. In describing embodiments, the width Wp of the pixel defining layer PDL may refer to a maximum width of the pixel defining layer PDL between adjacent emission areas EA, for example, a width of a bottom surface of the pixel defining layer PDL.

On the other hand, the bank BK may include a colored colorant, for example, a purple colorant, having a lower optical density than the black colorant, and accordingly, the partition wall portion BKa having a finer width Wb1 may be stably formed by exposing a bank material layer for forming the bank BK in an exposure process or the like. For example, the width Wb1 of the partition wall portion BKa of the bank BK may be smaller than 10 μm. As an example, the width Wb1 of the partition wall portion BKa of the bank BK may be approximately 4 μm to 6 μm. In this case, the partition wall portion BKa of the bank BK may be formed as a fine pattern having the width Wb1 smaller than the width Wp of the pixel defining layer PDL by approximately 4 μm or more. Accordingly, spaces in which the light conversion members CV are disposed may be expanded or secured, and the aperture ratio of the light conversion layer CVL may be increased.

The extending portions BKb may extend in an edge direction from the lower end portion of the partition wall portion BKa toward the light transmitting areas TA. For example, the extending portions BKb may be portions extending in the horizontal direction from the lower end portion of the partition wall portion BKa toward the light transmitting areas TA. Accordingly, the bank BK may have a fine width corresponding to the width Wb1 of the partition wall portion BKa on the top surface facing the light emitting surface of the display panel 100, while may have a width Wb2 increased by a length (2*ΔL) extending in both directions on the bottom surface including the extending portions BKb. As the bank BK includes the extending portions BKb, the lateral light LL traveling toward the light transmitting area TA of the adjacent pixel PX among the light emitted from the light emitting element ED of the pixel PX may be appropriately blocked or reduced. For example, the extending portion BKb of the bank BK may form an integrated light blocking portion of the bank BK (e.g., an integrated lateral light blocking pattern of the bank BK), and in particular, may contribute to effectively blocking or reducing lateral leaked light occurring between the light emitting element layer EDL and the light conversion layer CVL.

In an embodiment, a maximum width of the bank BK may be less than or equal to the width Wp of the pixel defining layer PDL, and the bank BK may not invade the emission areas EA defined by the pixel defining layer PDL. For example, the bottom surface of the bank BK including the extending portions BKb may have a width Wb2 less than or equal to the width Wp of the pixel defining layer PDL, and may completely overlap the pixel defining layer PDL.

A structure in which the width Wb2 of the bottom surface of the bank BK including the extending portions BKb is the same as the width Wp of the bottom surface of the pixel defining layer PDL has been illustrated in FIG. 9. However, embodiments are not limited thereto. For example, the width Wb2 of the bottom surface of the bank BK may also be greater than the width Wb1 of the partition wall portion BKa of the bank BK and smaller than the width Wp of the bottom surface of the pixel defining layer PDL.

In an embodiment, the width Wb2 of the bottom surface of the bank BK including the extending portions BKb may be substantially the same as or similar to the width Wp of the pixel defining layer PDL. For example, each of the extending portions BKb may extend from the partition wall portion BKa in one direction by a length (ΔL) of 2 μm or more, and accordingly, the width Wb2 of the bottom surface of the bank BK including the extending portions BKb may be greater than the width Wb1 of the partition wall portion BKa by 4 μm or more. As the width Wb2 of the bottom surface of the bank BK is increased or maximized within a range in which the emission areas EA are not invaded, an aperture ratio of the pixels PX may be secured, and the lateral light (e.g., LL in FIG. 7) traveling toward the light transmitting areas TA of the adjacent pixels PX among the light emitted from the light emitting elements ED of the pixels PX may be more effectively blocked or reduced.

In an embodiment, a thickness TH1 (or a height) of the extending portion BKb may be changed depending on a material or light blocking performance of the bank BK. As an example, the thickness TH1 of the extending portion BKb may be greater than or equal to a minimum thickness at which a meaningful light blocking effect may be obtained according to the optical density of the bank BK. In an embodiment, the bank BK may include a purple colorant, and the thickness TH1 of the extending portion BKb of the bank BK may be 2 μm or more. Accordingly, light (e.g., blue light) incident from the light emitting element ED of the surrounding pixel PX onto the extending portion BKb may be effectively blocked.

In an embodiment, the thickness TH1 of the extending portion BKb may be less than or equal to half of the total thickness of the bank BK. Accordingly, a reduction of areas of the light transmitting areas TA, volumes of the light conversion members CV, and/or the aperture ratio of the light conversion layer CVL may be prevented or minimized by the extending portions BKb. As an example, the thickness TH1 of the extending portion BKb may be 30% or less of the total thickness of the bank BK, and may be adjusted or optimized depending on the optical density according to the material or the like of the bank BK. In addition, the extending portion BKb may be formed at the thickness TH1 greater than or equal to a minimum thickness suitable for stably forming the extending portion BKb in a process of forming the bank BK.

In an embodiment, the bank BK may include a hydrophobic polymer. For example, the bank BK may be made of a resin composition including a hydrophobic polymer. Accordingly, durability of the bank BK may be improved, and the extending portion BKb may be prevented from being lost in the process of forming the bank BK.

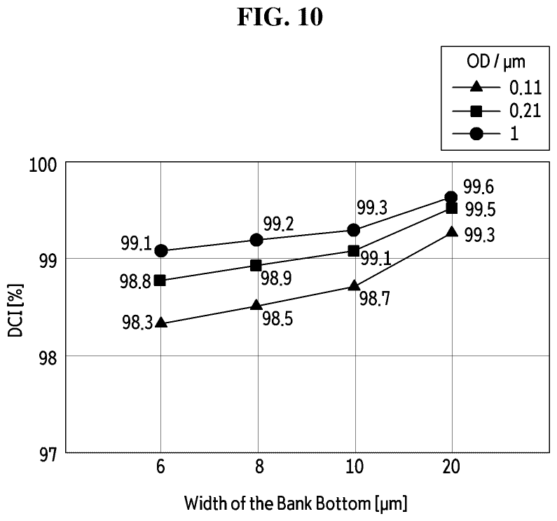

FIG. 10 is a graph illustrating color expressiveness of the display device according to characteristics of a bank. For example, FIG. 10 illustrates color reproducibility of the display device 1 according to the optical density OD of the bank BK and the width (e.g., Wb2 of FIG. 9) of the bottom surface of the bank BK based on a DCI-P3 color space.

Referring to FIG. 10, as the optical density OD of the bank BK increases, the color expressiveness of the display device 1 may be improved. For example, as the optical density OD of the bank BK increases, a light blocking rate of the bank BK may increase, such that the lateral light incident onto the bank BK may be more effectively blocked, and accordingly, the color reproducibility and/or a color matching rate (or color accuracy) of the display device 1 may be improved.

In some embodiments, the optical density OD of the bank BK may be adjusted by adjusting a type, a composition ratio, and the like, of the material included in the bank BK. As an example, the optical density OD of the bank BK may be increased by adjusting or optimizing a type and/or a composition ratio of the material included in the bank BK. Accordingly, the lateral leaked light of the display device 1 may be more effectively blocked, and the color reproducibility and/or the color matching rate of the display device 1 may be effectively improved.

In addition, when the width of the bottom surface of the bank BK increases, the color expressiveness of the display device 1 may increase. For example, as the width of the bottom surface of the bank BK increases, a ratio of light blocked by the bank BK among the lateral light traveling toward the light transmitting area TA of the adjacent pixel PX may increase. Accordingly, the color reproducibility and/or the color matching rate of the display device 1 may be improved.

As in an embodiment of FIGS. 7 and 9, when the display device 1 includes the bank BK including the partition wall portion BKa and the extending portions BKb, the aperture ratio of the light conversion layer CVL corresponding to (e.g., proportional to) areas of the light transmitting areas TA may be secured or improved, and the width Wb1 of the bottom surface of the bank BK may be secured or expanded to improve the color reproducibility and/or the color matching rate (or the color accuracy) of the display device 1. In some embodiments, at least one of the width Wb2 of the bottom surface of the bank BK including the extending portions BKb and the thickness TH1 of the extending portion BKb may be adjusted within a range in which the light blocking performance of the bank BK may be secured. Alternatively, the light blocking performance of the bank BK may be adjusted or optimized by adjusting at least one of the width Wb2 of the bottom surface of the bank BK including the extending portions BKb and the thickness TH1 of the extending portion BKb.

For example, when the optical density of the bank BK including the extending portions BKb increases, the thickness TH1 of the extending portion BKb may be reduced or minimized within a range in which the light blocking performance of the extending portion BKb may be secured. For example, the extending portion BKb may be formed at a limited thickness so as to secure the areas of the light transmitting areas TA (or the spaces in which the light conversion members CV are disposed) and so as not to impede the aperture ratio. As an example, the extending portion BKb may be formed at a minimum thickness (e.g., 2 μm) at which light blocking performance enough to block or reduce the lateral light LL may be secured or formed at a thickness close to the minimum thickness.

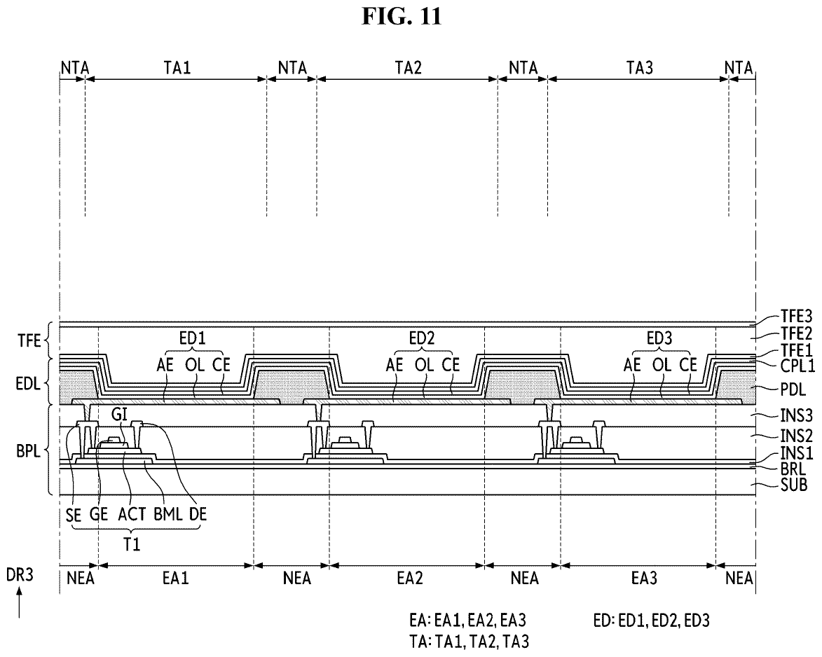

FIGS. 11 to 16 are cross-sectional views illustrating a method of manufacturing the display device according to an embodiment. For example, FIGS. 11 to 16 illustrate processes of forming the light emitting unit 110 among processes of manufacturing the display panel 100 of the display device 1 according to an embodiment of FIGS. 1 to 9.

Referring to FIG. 11 in addition to FIGS. 1 to 9, the substrate SUB may be provided as a base member of the light emitting unit 110, and the backplane layer BPL, the light emitting element layer EDL, and the encapsulation layer TFE may be sequentially formed. For example, the backplane layer BPL may be formed by forming the circuit elements of each pixel PX including the first transistor T1 and the insulating layers of the backplane layer BPL on the substrate SUB.

Thereafter, the light emitting element layer EDL including the pixel defining layer PDL defining the emission areas EA and the light emitting elements ED disposed in the emission areas EA may be formed on the backplane layer BPL. For example, the first electrodes AE of the light emitting elements ED, the pixel defining layer PDL, the light emitting layer OL and the second electrode CE of the light emitting elements ED, and the first capping layer CPL1 may be sequentially formed on the backplane layer BPL.

Thereafter, the encapsulation layer TFE may be formed on the light emitting element layer EDL. For example, the first encapsulation layer TFE1, the second encapsulation layer TFE2, and the third encapsulation layer TFE3 may be sequentially formed on the first capping layer CPL1 (or the second electrode CE of the light emitting elements ED).

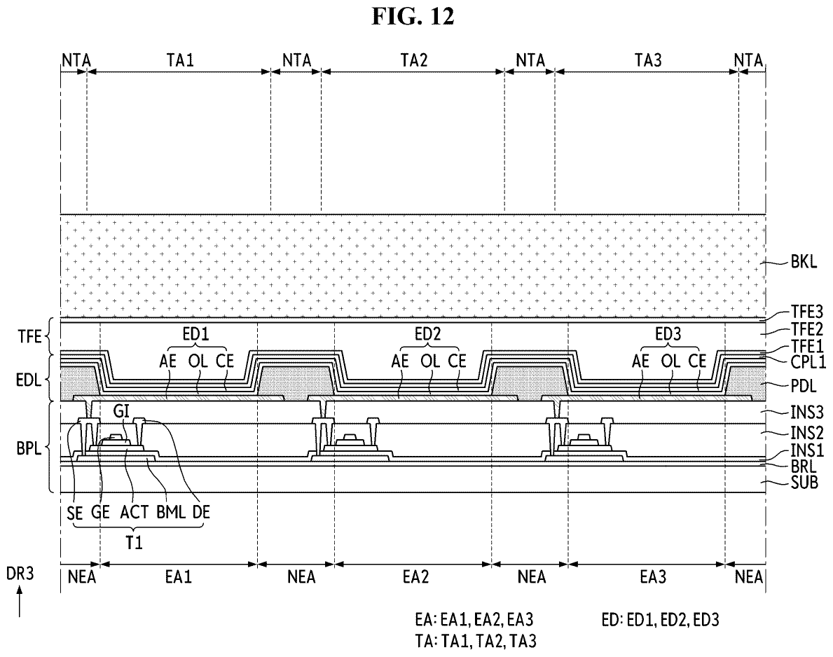

Referring to FIGS. 12 to 16, the light conversion layer CVL including the bank BK defining the light transmitting areas TA corresponding to the emission areas EA and the light conversion members CV disposed in the light transmitting areas TA may be formed on the encapsulation layer TFE (or the light emitting element layer EDL). In some embodiments, the bank BK may be first formed on the encapsulation layer TFE, and the light conversion members CV may be formed in the light transmitting areas TA defined by the bank BK.

For example, as illustrated in FIG. 12, a bank material layer BKL may be formed on the encapsulation layer TFE. The bank material layer BKL may be made of a material exemplified as the material of the bank BK. As an example, the bank material layer BKL may be formed by applying a resin composition including a photocurable material (e.g., a negative photoresist) onto the encapsulation layer TFE.

In an embodiment, the bank material layer BKL may include a deep portion curing initiator and a hydrophobic polymer. Accordingly, in a subsequent process, the bank BK having a target shape and/or size may be appropriately formed by more precisely patterning the bank material layer BKL. In addition, the bank material layer BKL may include a polymer and a monomer, and by adjusting a ratio between the polymer and the monomer used to form the bank material layer BKL to control a film quality of the bank material layer BKL, it is possible to prevent or minimize loss of the extending portions BKb in a process of forming the bank BK.

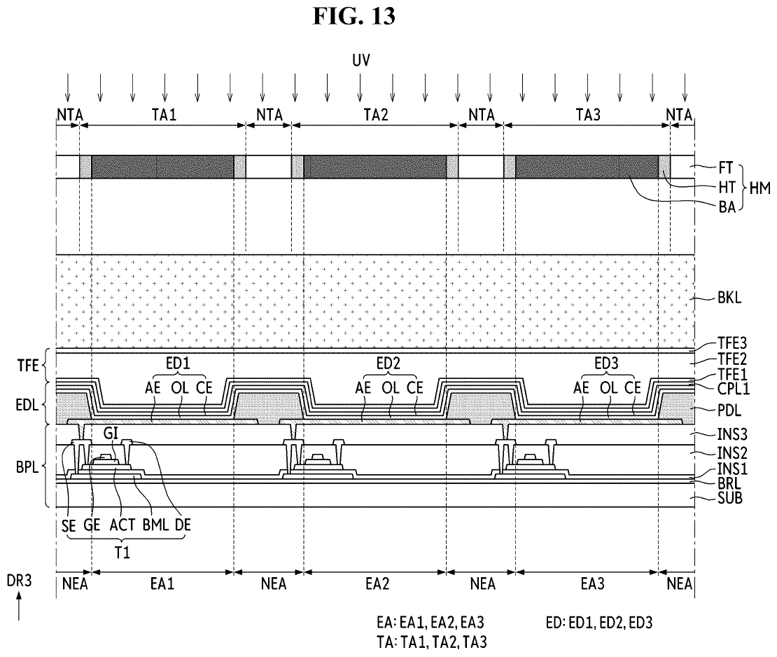

Thereafter, as illustrated in FIG. 13, a half-tone mask HM may be disposed on the bank material layer BKL, and the bank material layer BKL may be exposed. For example, a full-tone portion FT of the half-tone mask HM may be disposed on a portion of the bank material layer BKL (e.g., a portion of the bank material layer BKL disposed in the light blocking area NTA) overlapping a central portion of the pixel defining layer PDL, half-tone portions HT of the half-tone mask HM may be disposed on other portions of the bank material layer BKL (e.g., portions of the bank material layer BKL disposed in areas where the extending portions BKb of the bank BK are to be formed) overlapping edge portions of the pixel defining layer PDL, and non-tone portions BA of the half-tone mask HM may be disposed on the remaining portions of the bank material layer BKL (e.g., portions of the bank material layer BKL disposed on the light emitting elements ED located in the emission areas EA) overlapping openings (e.g., the first openings OP1 of FIG. 5) of the pixel defining layer PDL. In addition, in a state in which the half-tone mask HM is disposed on the bank material layer BKL, the bank material layer BKL may be irradiated with ultraviolet rays UV.

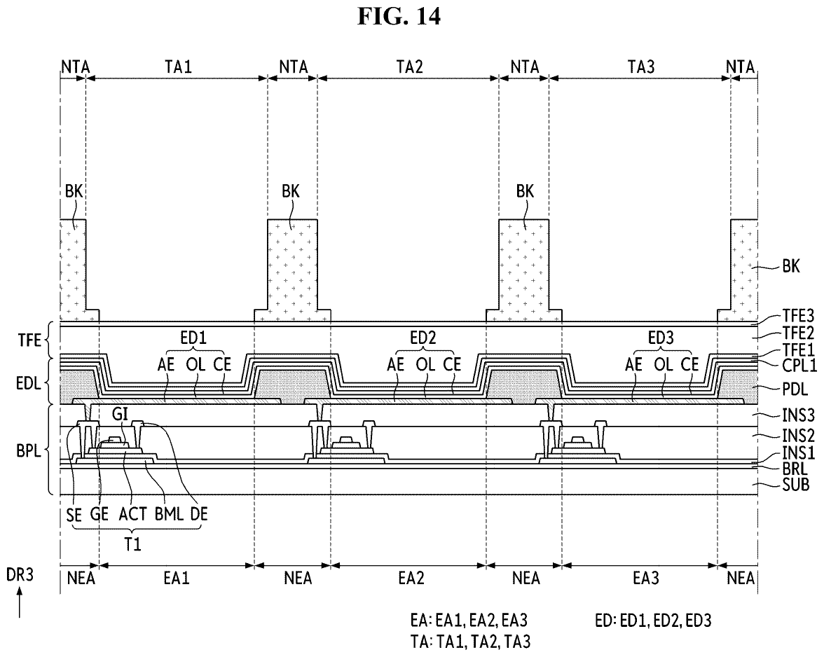

Thereafter, as illustrated in FIG. 14, the bank BK may be formed by removing portions of the bank material layer BKL that are not exposed. For example, the bank BK may be formed by developing the bank material layer BKL.

A portion of the bank material layer BKL completely exposed by the full-tone portion FT of the half-tone mask HM may be formed at the greatest thickness to form the partition wall portion BKa (see FIG. 9) of the bank BK. Other portions of the bank material layer BKL exposed through the half-tone portions HT of the half-tone mask HM may only partially remain at a lower portion of the bank material layer BKL to form the extending portions BKb (see FIG. 9) of the bank BK. The remaining portions of the bank material layer BKL hidden by the non-tone portions BA of the half-tone mask HM may be removed. Accordingly, the bank BK having a screw-shaped cross section may be formed.

Since the deep portion curing initiator and the hydrophobic polymer are added when the bank material layer BKL is formed as described above, the extending portions BKb may be easily formed at a lower end portion of the bank BK. For example, a lower end portion of the bank material layer BKL located below the half-tone portions HT of the half-tone mask HM may be sufficiently cured by the deep portion curing initiator. In addition, durability of the bank BK may be enhanced by the hydrophobic polymer. Accordingly, the extending portions BKb of the bank BK may be prevented from being lost in a developing process or the like, and may be prevented from being lifted or damaged. In addition, by adjusting a ratio between the monomer and the polymer included a material (e.g., a resin composition) used to form the bank material layer BKL to control the film quality of the bank material layer BKL, it is possible to more precisely or stably form the bank BK in a target shape.

In embodiments, by forming the bank BK including the partition wall portion BKa and the extending portions BKb using the half-tone mask HM, it is possible to form the bank BK according to embodiments without an additional mask process. Accordingly, a manufacturing process of the display device 1 may be simplified, and manufacturing efficiency of the display device 1 may be increased. In addition, in embodiments, the partition wall portion BKa and the extending portions BKb are formed integrally with each other, and thus, an alignment degree between the partition wall portion BKa defining the light transmitting areas TA and the extending portions BKb for blocking the lateral leaked light may be secured.

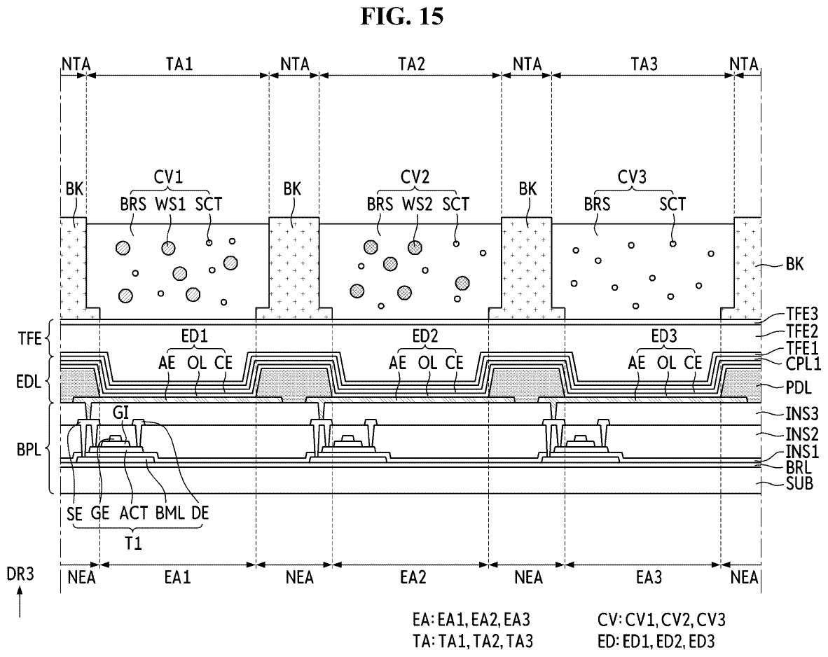

Thereafter, as illustrated in FIG. 15, the light conversion members CV may be formed in the light transmitting areas TA defined by the banks BK. For example, the first light conversion member CV1, the second light conversion member CV2, and the third light conversion member CV3 may be included in the first light transmitting area TA1, the second light transmitting area TA2, and the third light transmitting area TA3, respectively. Each of the light conversion members CV may include the base resin BRS, and may optionally further include the light diffusing agents SCT. In addition, the first light conversion member CV1 and the second light conversion member CV2 may further include the first wavelength shifters WS1 and the second wavelength shifters WS2, respectively. In an embodiment, the light conversion members CV may be formed by an inkjet method, but a method of forming the light conversion members CV is not limited thereto.

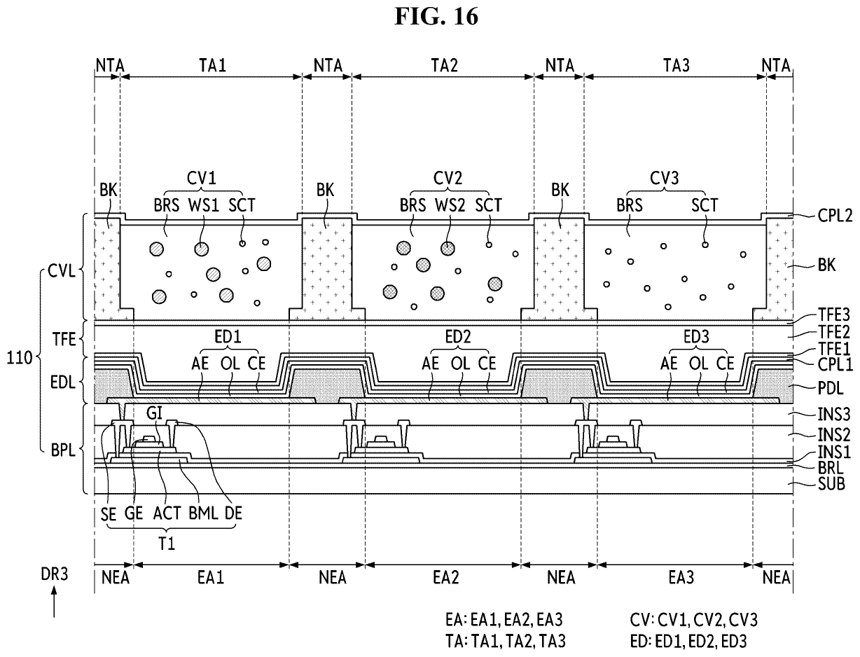

Thereafter, as illustrated in FIG. 16, the second capping layer CPL2 covering the bank BK and the light conversion members CV may be formed. The second capping layer CPL2 may be made of a material exemplified as the material of the second capping layer CPL2.

The light emitting unit 110 of the display panel 100 may be formed by the processes described with reference FIGS. 11 to 16. After the light emitting unit 110 is formed, a process of applying the filler 170, a process of bonding the light emitting unit 110 and the color filter unit 130 to each other using the sealant 150, and the like, may be performed. Accordingly, the display panel 100 of the display device 1 according to an embodiment of FIGS. 1 to 9 may be manufactured.

The display device 1 according to at least one of the above-described embodiments may be applied to various electronic devices. An electronic device according to an embodiment may include the display device 1 described above (or a display module including the display panel 100 according to at least an embodiment), and may further include a module or a device having other additional functions in addition to the display device 1.

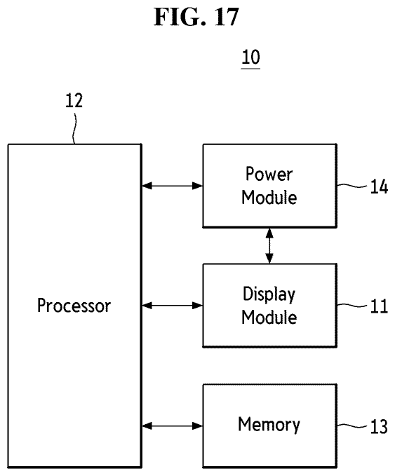

FIG. 17 is a block diagram of an electronic device according to an embodiment.

Referring to FIG. 17, an electronic device 10 according to an embodiment may include a display module 11, a processor 12, a memory 13, and a power module 14.

The electronic device 10 may output various information in the form of an image through the display module 11. For example, when the processor 12 executes an application stored in the memory 13, image information provided by the application may be provided to a user through the display module 11.

The display module 11 may include the display panel 100 for displaying an image. As an example, the display module 11 may include the display panel 100 according to at least one of the above-described embodiments.

The processor 12 may include at least one of a central processing unit (CPU), an application processor (AP), a graphic processing unit (GPU), a communication processor (CP), an image signal processor (ISP), and a controller.

The memory 13 may store data information for an operation of the processor 12 or the display module 11. For example, the memory 13 may store an image data signal and/or an input control signal.

The processor 12 may control the display module 11 using the information stored in the memory 13. The processor 12 may transmit the image data signal and/or the input control signal stored in the memory 13 to the display module 11. For example, when the processor 12 executes an application stored in the memory 13, the image data signal and/or the input control signal may be transmitted to the display module 11, and the display module 11 may process the received signal and output image information through a display screen. The processor 12 may include one or more processors. In implementations with more than one processor, the processors may work individually, collectively or as part of a collective. For example, as part of a collective two out of three processors may operate together to execute instructions for an application.

The power module 14 may include a power supply module such as a power adapter or a battery device and a power conversion module converting power supplied by the power supply module to generate power for an operation of the electronic device 10.

At least one of the respective components of the above-described electronic device 10 may be included in the display device 1 according to the above-described embodiments. In addition, some of individual modules functionally included in one module may be included in the display device 1, and the others of the individual modules may be provided separately from the display device 1. For example, the display device 1 may include the display module 11, and the processor 12, the memory 13, and the power module 14 may be provided in the form of other devices within the electronic device 10 rather than the display device 1.

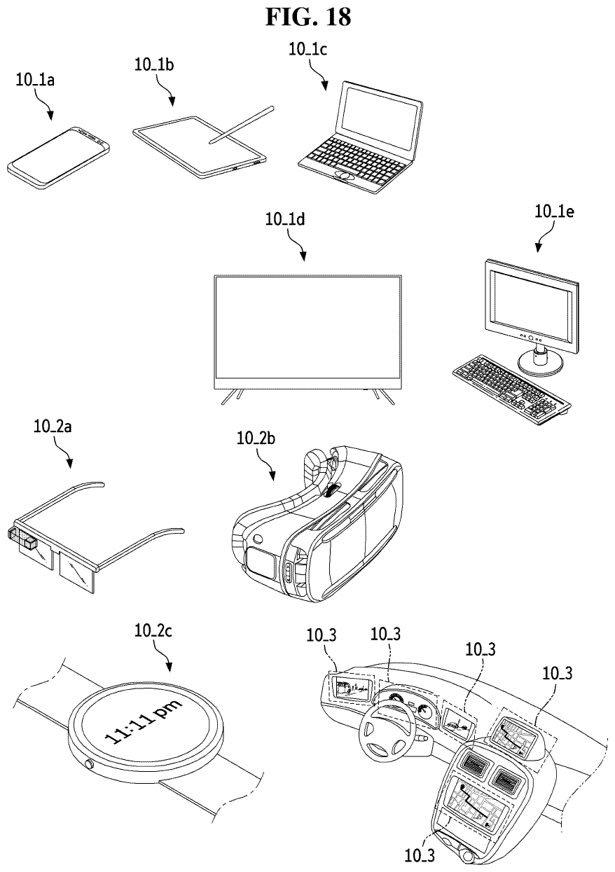

FIG. 18 is schematic view of electronic devices according to various embodiments.

Referring to FIG. 18, various electronic devices to which the display device 1 according to embodiments is applied may include not only image display electronic devices such as a smartphone 10_1a, a tablet PC 10_1b, a laptop computer 10_1c, a television (TV) 10_1d, and a monitor 10_1e for a desktop computer, but also wearable electronic devices including display modules, such as a smart glasses 10_2a, a head mounted display 10_2b, and a smart watch 10_2c, and vehicle electronic devices 10_3 including display modules, such as a center information display (CID) disposed on an instrument board, a center fascia, or a dashboard of a vehicle and a room mirror display.

As described above, with the display device 1, the electronic device 10, and the method of manufacturing the display device 1 according to embodiments, by forming the extending portions BKb integrally extending from the partition wall portion BKa of the bank BK at the lower end portion of the bank BK defining the light transmitting areas TA where the light incident from the light emitting elements ED is converted and/or transmitted, it is possible to effectively block or reduce the lateral leaked light between the pixels PX. Accordingly, color distortion due to light interference between the pixels PX may be prevented or minimized, and the color expressiveness (e.g., the color matching rate and/or the color reproducibility) of the display device 1 and the electronic device 10 may be improved.

In some embodiments, the bank BK including the extending portions BKb may have a width (e.g., the width W1b of the bottom surface of the bank BK) less than or equal to the width Wp of the pixel defining layer PDL, and may not invade the emission areas EA defined by the pixel defining layer PDL. Accordingly, the aperture ratio of the display device 1 and the electronic device 10 may be secured or improved, and the color expressiveness of the display device 1 and the electronic device 10 may be improved.

In some embodiments, the partition wall portion BKa and the extending portions BKb of the bank BK may be simultaneously formed using the half-tone mask HM. Accordingly, manufacturing efficiency of the display device 1 and the electronic device 10 may be increased. In addition, the alignment degree between the integrated light blocking portion (e.g., the wing-shaped extending portion BKb) formed at the lower end portion of the bank BK and the partition wall portion BKa of the bank BK may be secured.

In concluding the detailed description, those skilled in the art will appreciate that many variations and modifications can be made to the embodiments without substantially departing from the principles of the present disclosure. Therefore, the disclosed embodiments are used in a generic and descriptive sense only and not for purposes of limitation.

What is claimed is:

1. A display device comprising:
a substrate;
a light emitting element layer disposed on the substrate and including a pixel defining layer defining emission areas and light emitting elements disposed in the emission areas; and
a light conversion layer disposed on the light emitting element layer and including a bank defining light transmitting areas each of which is disposed on one of the emission areas and light conversion members disposed in the light transmitting areas,
wherein the bank includes:
a partition wall portion having a width smaller than a width of the pixel defining layer and overlapping a central portion of the pixel defining layer; and
an extending portion extending from a lower end portion of the partition wall portion toward the light transmitting areas.

2. The display device of claim 1, wherein a bottom surface of the bank including the extending portion has a width less than or equal to the width of the pixel defining layer and the bottom surface of the bank including the extending portion completely overlaps the pixel defining layer.

3. The display device of claim 1, wherein the bank includes a hydrophobic polymer.

4. The display device of claim 1, wherein the pixel defining layer includes a first colorant, and
the bank includes a second colorant having a lower optical density than the first colorant.

5. The display device of claim 4, wherein the first colorant is a black colorant, and the second colorant is a purple colorant.

6. The display device of claim 1, wherein a thickness of the extending portion of the bank is 2 μm or more.

7. The display device of claim 1, wherein the emission areas include a first emission area, a second emission area, and a third emission area, and
the light emitting elements include a first light emitting element, a second light emitting element, and a third light emitting element respectively disposed in the first emission area, the second emission area, and the third emission area and each of the first light emitting element, the second light emitting element and the third light emitting element emitting light of the same color.

8. The display device of claim 7, wherein the light conversion members include:
a first light conversion member disposed on the first light emitting element and converting the light emitted from the first light emitting element into light of a first color;
a second light conversion member disposed on the second light emitting element and converting the light emitted from the second light emitting element into light of a second color; and
a third light conversion member disposed on the third light emitting element and transmitting the light emitted from the third light emitting element.

9. The display device of claim 8, further comprising a color filter unit disposed on the light conversion layer,
wherein the color filter unit includes:
a first color filter disposed on the first light conversion member;
a second color filter disposed on the second light conversion member; and
a third color filter disposed on the third light conversion member.

10. The display device of claim 7, wherein each of the light emitting elements includes a first electrode, a light emitting layer, and a second electrode that are sequentially disposed on the substrate,
the first electrode in each of the light emitting elements is disposed in each of the emission areas as separate units, and
the light emitting layer and the second electrode are disposed over an entire display area including the emission areas.

11. The display device of claim 1, wherein the pixel defining layer includes a first opening at least partially disposed around a first emission area of the emission areas,
the partition wall portion of the bank includes a second opening at least partially disposed around a first light transmitting area overlapping the first emission area among the light transmitting areas, and
an area of the second opening is greater than an area of the first opening.

12. The display device of claim 11, wherein in plan view, the first opening is disposed inside the second opening.

13. The display device of claim 1, wherein the light transmitting areas are defined by the partition wall portion of the bank, and
in plan view, sizes of the light transmitting areas are greater than sizes of the emission areas, and edges of the light transmitting areas are located outside the emission areas.

14. An electronic device comprising:
a display module including a display panel; and
a processor transmitting an image data signal to the display module,
wherein the display panel includes:
a substrate;
a light emitting element layer disposed on the substrate and including a pixel defining layer defining emission areas and light emitting elements disposed in the emission areas; and
a light conversion layer disposed on the light emitting element layer and including a bank defining light transmitting areas each of which is disposed on one of the emission areas and light conversion members disposed in the light transmitting areas, and
the bank includes:
a partition wall portion having a width smaller than a width of the pixel defining layer and overlapping a central portion of the pixel defining layer; and
an extending portion extending from a lower end portion of the partition wall portion toward the light transmitting areas.

15. The electronic device of claim 14, wherein a bottom surface of the bank including the extending portion has a width less than or equal to the width of the pixel defining layer and the bottom surface of the bank including extending portion completely overlaps the pixel defining layer.

16. The electronic device of claim 14, wherein the bank includes a hydrophobic polymer.

17. The electronic device of claim 14, wherein the pixel defining layer includes a first colorant, and
the bank includes a second colorant having a lower optical density than the first colorant.

18. The electronic device of claim 14, wherein the emission areas include a first emission area, a second emission area, and a third emission area,
the light emitting elements include a first light emitting element, a second light emitting element, and a third light emitting element respectively disposed in the first emission area, the second emission area, and the third emission area and each of the first light emitting element, the second light emitting element and the third light emitting element emitting light of the same color, and
the light conversion members include a first light conversion member disposed on the first light emitting element and converting the light emitted from the first light emitting element into light of a first color, a second light conversion member disposed on the second light emitting element and converting the light emitted from the second light emitting element into light of a second color, and a third light conversion member disposed on the third light emitting element and transmitting the light emitted from the third light emitting element.

19. A method of manufacturing a display device, comprising:
forming a light emitting element layer on a substrate, the light emitting element layer including a pixel defining layer defining emission areas and light emitting elements disposed in the emission areas; and
forming a light conversion layer on the light emitting element layer, the light conversion layer including a bank defining light transmitting areas each of which is disposed on one of the emission areas and light conversion members disposed in the light transmitting areas,
wherein the forming of the bank includes:
forming a bank material layer on the light emitting element layer, the bank material layer including a deep portion curing initiator and a hydrophobic polymer;
disposing a half-tone mask on the bank material layer and exposing the bank material layer using the half-tone mask; and
forming the bank by developing the bank material layer.

20. The method of manufacturing a display device of claim 19, wherein in the exposing of the bank material layer using the half-tone mask:
a full-tone portion of the half-tone mask is disposed on a portion of the bank material layer overlapping a central portion of the pixel defining layer,
half-tone portions of the half-tone mask are disposed on other portions of the bank material layer overlapping edge portions of the pixel defining layer, and
non-tone portions of the half-tone mask are disposed on the remaining portions of the bank material layer overlapping openings of the pixel defining layer.
